(19) United States
(12) Patent Application Publication
(10) Pub. No.: US 2016/0071941 A1
(43) Pub. Date: Mar. 10, 2016

(54) FIELD EFFECT TRANSISTOR AND MAGNETIC MEMORY

(71) Applicant: Keisuke NAKATSUKA, Seoul (KR)

(72) Inventor: Keisuke NAKATSUKA, Seoul (KR)

(21) Appl. No.: 14/643,856

(22) Filed: Mar. 10, 2015

Related U.S. Application Data
(60) Provisional application No. 62/047,588, filed on Sep. 8, 2014.

(51) Int. Cl. H01L 29/423; H01L 27/22; H01L 29/78

(52) U.S. Cl. CPC H01L 29/4236; H01L 29/7827; H01L 27/228

(57) ABSTRACT

According to one embodiment, a field effect transistor includes a semiconductor layer having a first trench, a first gate insulating layer on a bottom surface of the first trench, a first gate electrode on the first gate insulating layer, first and second impurity regions in the semiconductor layer, the first and second impurity regions exposing on first and second side surfaces of the first trench in a first direction, respectively, a first interlayer insulating layer between the first gate electrode and the first impurity region in the first trench, a second interlayer insulating layer between the first gate electrode and the second impurity region in the first trench, and third and fourth impurity regions in the semiconductor layer, the third and fourth impurity regions exposing on the bottom surface of the first trench.

### CROSS-REFERENCE TO RELATED APPLICATIONS

This application claims the benefit of U.S. Provisional Application No. 62/047,588, filed Sep. 8, 2014, the entire contents of which are incorporated herein by reference.

### FIELD

Embodiments described herein relate generally to a field effect transistor and a magnetic memory.

### BACKGROUND

Recently, various novel next-generation memories replacing existing semiconductor memories such as flash memories and DRAM have been proposed. Among the memories, a magnetic random access memory (hereinafter called MRAM) capable of high-speed operation and microminiaturization is a most promising candidate as a replacement of the DRAM. A memory element of the MRAM comprises a magnetoresistive element and a select transistor.

The magnetoresistive element comprises, for example, a reference layer having invariable magnetization, a memory layer having variable magnetization, and a tunnel barrier layer deposited between the layers. In addition, the select transistor is, for example, a field effect transistor (hereinafter called FET).

### BRIEF DESCRIPTION OF THE DRAWINGS

FIG. 1 is a cross-sectional view showing a device structure of a magnetic memory according to an embodiment.

FIG. 2 is a cross-sectional view showing a device structure of a magnetic memory according to a comparative example.

FIG. 3 is a plan view showing a configuration example of a memory cell array.

FIG. 4 is a cross-sectional view seen along line IV-IV in FIG. 3.

FIG. 5 is a cross-sectional view seen along line V-V in FIG. 3.

FIG. 6 is a cross-sectional view seen along line VI-VI in FIG. 3.

FIG. 7 is a cross-sectional view seen along line VII-VII in FIG. 3.

FIG. 8 is a cross-sectional view seen along line VIII-VIII in FIG. 3.

FIG. 9 is a circuit diagram showing an equivalent circuit of the memory cell array shown in FIGS. 3 to 8.

FIG. 10 is a plan view showing a first configuration example of an FET serving as a peripheral circuit.

FIG. 11A, FIG. 11B, and FIG. 11C are cross-sectional views seen along line XI-XI in FIG. 10.

FIG. 12A and FIG. 12B are cross-sectional views seen along line XII-XII in FIG. 10.

FIG. 13 is a plan view showing a step of a method of manufacturing the FET shown in FIG. 10.

FIG. 14 is a cross-sectional view seen along line XIV-XIV in FIG. 13.

FIG. 15 is a plan view showing a step of the method of manufacturing the FET shown in FIG. 10.

FIG. 16 is a cross-sectional view seen along line XVI-XVI in FIG. 15.

FIG. 17A and FIG. 17B are cross-sectional views seen along line XVII-XVII in FIG. 15.

FIG. 18, FIG. 19, FIG. 20A, FIG. 20B, FIG. 21A, FIG. 21B, FIGS. 22 to 26, FIG. 27A, FIG. 27B, and FIGS. 28 to 30 are cross-sectional views showing steps of the method of manufacturing the FET shown in FIG. 10.

FIG. 31 is a plan view showing a second configuration example of an FET serving as a peripheral circuit.

FIG. 32A and FIG. 32B are cross-sectional views seen along line XXXII-XXXII in FIG. 31.

FIG. 33A and FIG. 33B are cross-sectional views seen along line XXXIII-XXXIII in FIG. 31.

FIG. 34 is a plan view showing a step of a method of manufacturing the FET shown in FIG. 31.

FIG. 35 is a cross-sectional view seen along line XXXV-XXXV in FIG. 34.

FIG. 36 is a plan view showing a step of the method of manufacturing the FET shown in FIG. 31.

FIG. 37 is a cross-sectional view seen along line XXXVII-XXXVII in FIG. 36.

FIG. 38A and FIG. 38B are cross-sectional views seen along line XXXVIII-XXXVIII in FIG. 36.

FIGS. 39 to 43, FIG. 44A, FIG. 44B, and FIGS. 45 to 49 are cross-sectional views showing steps of the method of manufacturing the FET shown in FIG. 31.

### DETAILED DESCRIPTION

In general, according to one embodiment, a field effect transistor comprises: a semiconductor layer having a first trench; a first gate insulating layer on a bottom surface of the first trench; a first gate electrode on the first gate insulating layer; first and second impurity regions in the semiconductor layer, the first and second impurity regions exposing on first and second side surfaces of the first trench in a first direction, respectively; a first gate sidewall insulating layer between the first gate electrode and the first impurity region in the first trench, a width of the first gate sidewall insulating layer in an in-plane direction which is parallel to an upper surface of the semiconductor layer being larger than a thickness of the first gate insulating layer in a perpendicular direction which is perpendicular to the upper surface of the semiconductor layer; a second gate sidewall insulating layer between the first gate electrode and the second impurity region in the first trench, a width of the second gate sidewall insulating layer in the in-plane direction being larger than the thickness of the first gate insulating layer in the perpendicular direction; and third and fourth impurity regions in the semiconductor layer, the third and fourth impurity regions exposing on the bottom surface of the first trench, the third impurity region having a impurity concentration lower than that of the first impurity region and being connected to the first impurity region, the fourth impurity region having a impurity concentration lower than that of the second impurity region and being connected to the second impurity region.

### EMBODIMENTS

Embodiments will be described hereinafter with reference to the accompanying drawings.

### 1. Device Structure

### Relationship Between Memory Cell Array and Peripheral Circuit

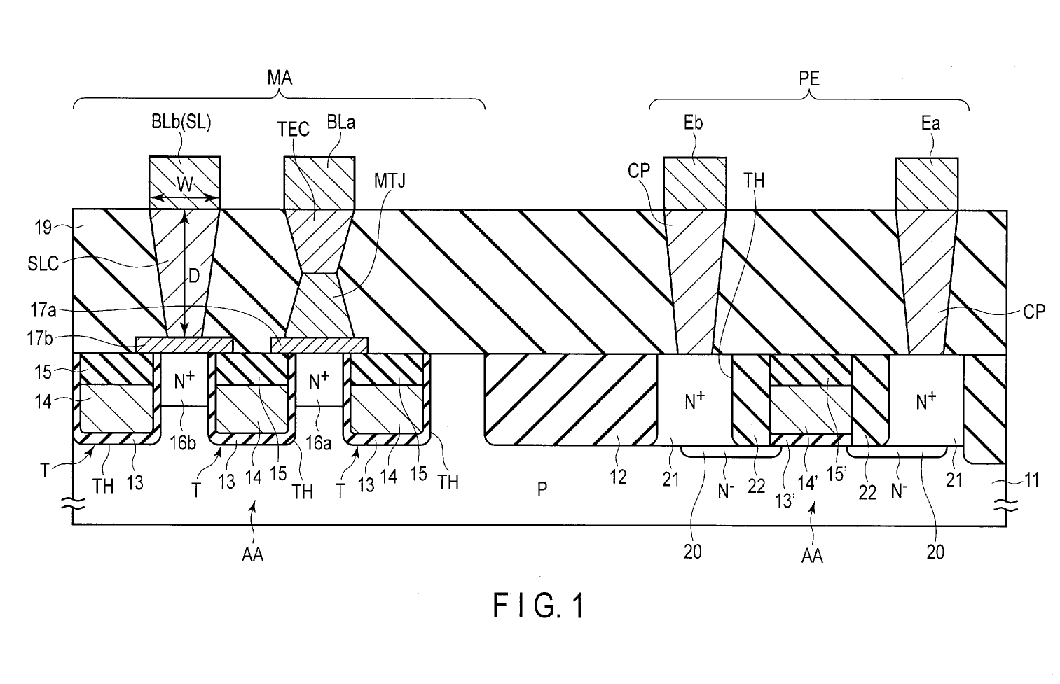

FIG. 1 shows a device structure of a magnetic memory according to one of the embodiments.

The figure shows parts of a memory cell array MA and a peripheral circuit PE in a magnetic memory, for example, an MRAM. The peripheral circuit PE indicates a circuit formed in an area other than the memory cell array MA, and comprises, for example, circuits formed in a core portion including the memory cell array MA such as a decoder and a driver, circuits formed outside the core portion such as a sense amplifier and a power supply circuit, etc.

The memory cell array MA includes a memory cell comprising a magnetoresistive element MTJ and a select transistor (FET) T.

Since the select transistor T aims at retention of a large power driving force, prevention of the short channel effect, etc. in accordance with microminiaturization of the memory cell, the transistor has a buried gate structure in which a gate electrode 14 is buried in a semiconductor substrate 11.

For example, an element isolation insulating layer 12 is arranged in the semiconductor substrate (semiconductor layer) 11. In the present example, the semiconductor substrate 11 is a P-type semiconductor substrate, which may be replaced with an N-type semiconductor substrate. The semiconductor substrate 11 surrounded by the element isolation insulating layer 12 becomes an active area AA.

A gate insulating layer 13 is arranged on an inner surface of a trench TH in the semiconductor substrate 11. A gate electrode 14 is disposed on the gate insulating layer 13 in the trench TH. A cap insulating layer 15 is disposed on the gate electrode 14. Source/drain regions (impurity regions) 16a and 16b are disposed in a surface region of the semiconductor substrate 11. In the present embodiment, the source/drain regions 16a and 16b are N-type regions, which may be replaced with P-type regions.

The semiconductor substrate 11 is, for example, a silicon substrate. The element isolation insulating layer 12 is, for example, a silicon oxide layer. The gate insulating layer 13 is, for example, a silicon oxide layer. The gate electrode 14 is, for example, a conductive polysilicon layer. The cap insulating layer 15 is, for example, a silicon nitride layer. The gate electrode 14 may have a metal gate structure. In this case, a gate electrode 14′ contains TiN, TaC, TaN, WN, W, etc.

Bottom electrodes 17a and 17b are disposed on the source/drain regions 16a and 16b, respectively. The magnetoresistive element MTJ is disposed on the bottom electrode 17a. An interlayer insulating layer 19 covers the magnetoresistive element MTJ. A bit line BLa is connected to the magnetoresistive element MTJ via a top electrode contact TEC. A bit line BLb (or a source line SL) is connected to the source/drain region 16b via a source line contact SLC.

The bottom electrodes 17a and 17b contain, for example, Al, Be, Mg, Ca, Sr, Ba, Sc, Y, La, Zr, Hf, etc. The bottom electrodes 17a and 17b may contain compounds such as HfB, MgAlB, HfAlB, ScAlB, ScHfB, and HfMgB.

The top electrode contact TEC and the source line contact SLC contain, for example, W, Ta, Ru, Ti, etc. The top electrode contact TEC and the source line contact SLC may contain compounds for barrier meal layers such as TaN and TiN.

One of features of the memory cell array MA is that the bottom electrode 17a is disposed directly on the source/drain region 16a. In other words, a bottom electrode contact is not connected between the bottom electrode 17a and the source/drain region 16a.

An alignment accuracy of the magnetoresistive element MTJ and the source/drain region 16a is thereby improved as alignment with the bottom electrode contact becomes unnecessary. In addition, increase in an aspect ratio (i.e., a ratio D/W of depth D to width W) of the source line contact SLC can be suppressed. As a result, a manufacturing yield of the magnetic memory can be improved.

These effects result from a device structure of the FET serving as the peripheral circuit PE.

In other words, the FET serving as the peripheral circuit PE has a buried gate structure, similarly to the select transistor T of the memory cell.

For example, a gate insulating layer 13′ is disposed on a bottom surface of the trench TH in the semiconductor substrate 11, in the active area AA. The gate electrode 14′ is disposed on the gate insulating layer 13′ in the trench TH. A cap insulating layer 15′ is disposed on the gate electrode 14′. A source/drain region (impurity region) 21 is disposed in a surface region of the semiconductor substrate 11. Electrodes Ea and Eb are connected to the source/drain regions 21 via source/drain contacts CP, respectively. In the present embodiment, the source/drain regions 21 are N-type regions. However, the semiconductor substrate may be in N type and the source/drain regions 21 may be in P type.

The gate insulating layer 13′ is, for example, a silicon oxide layer. The gate electrode 14′ is, for example, a conductive polysilicon layer. The cap insulating layer 15′ is, for example, a silicon nitride layer. The gate insulating layer 13′ may contain a high-k material. The high-k material indicates a material having a larger dielectric constant than a dielectric constant of the silicon oxide layer. For example, SiN, SiON, HfSiO₂, HfSiON, HfO₂, ZrO₂, HfZrOₓ, HfLaOₓ, etc. can be used as the high-k material.

The gate electrode 14′ may have a metal gate structure. In this case, the gate electrode 14′ contains TiN, TaC, TaN, WN, W, etc. The gate electrode 14′ may comprise the same structure (material) as the structure (material) of the gate electrode 14 of the select transistor T of the memory cell. In this case, processes of the memory cell array MA and the peripheral circuit PE can be made common.

In the peripheral circuit PE, unlike the select transistor T of the memory cell, a parasitic capacitance between the gate electrode 14′ and the source/drain region 21 should preferably be as small as possible from the viewpoint of high-speed operations. Thus, a gate sidewall insulating layer 22 is disposed between the gate electrode 14′ and the source/drain region 21.

The gate sidewall insulating layer 22 increases, for example, a distance between the gate electrode 14′ and the source/drain region 21 such that the parasitic capacitance generated therebetween becomes sufficiently small.

The width of the gate sidewall insulating layer 22 in the in-plane direction (i.e., a direction parallel to an upper surface of the semiconductor substrate 11) should be larger than, for example, two times or more as large as a thickness of the gate insulating layer 13′ in a perpendicular direction (i.e., a direction perpendicular to the upper surface of the semiconductor substrate 11). The gate sidewall insulating layer 22 may contain the same material as the material of the gate insulating layer 13′ or a material different therefrom.

The gate sidewall insulating layer 22 should desirably contain a low-k material for its purpose. The low-k material indicates a material having a smaller dielectric constant than a dielectric constant of the silicon oxide layer. For example, a porous silicon oxide layer can be used as the low-k material.

In the peripheral circuit PE, unlike the select transistor T of the memory cell, a channel mobility of electrons or pores should preferably be as large as possible from the viewpoint of high-speed operations. Thus, an extension region (halo region) 20 is disposed at a position where a channel region disposed immediately under the gate electrode 14′ is connected with the source/drain region 21.

In the present example, the extension region 20 is disposed at a position lower than the surface of the semiconductor substrate 11, more specifically, under the source/drain region 21, since the peripheral circuit PE has the buried gate structure. The extension region 20 is in the N type. However, when the source/drain region 21 is in the P type, the extension region 20 also needs to be in the P type.

Thus, the channel mobility of electrons and pores in the peripheral circuit PE can be improved by disposing the extension region 20.

In addition, an edge of the bottom surface and the side surface of the trench TH should desirably be rounded from the viewpoint of the channel mobility.

As described above, in the present embodiment, each of the select transistor T in the memory cell array MA and the FET in the peripheral circuit PE has the buried gate structure. For this reason, a probability of occurrence of misalignment can be lowered by omitting the bottom electrode contact, in the memory cell array MA. In addition, a new structure in which the FET is not merely set to be in the buried gate type, but the parasitic capacitance between the gate electrode 13′ and the source/drain region 21 is lowered and the channel mobility of electrons and pores is improved, is proposed in the peripheral circuit PE. Acceleration of the peripheral circuit PE can be thereby attempted.

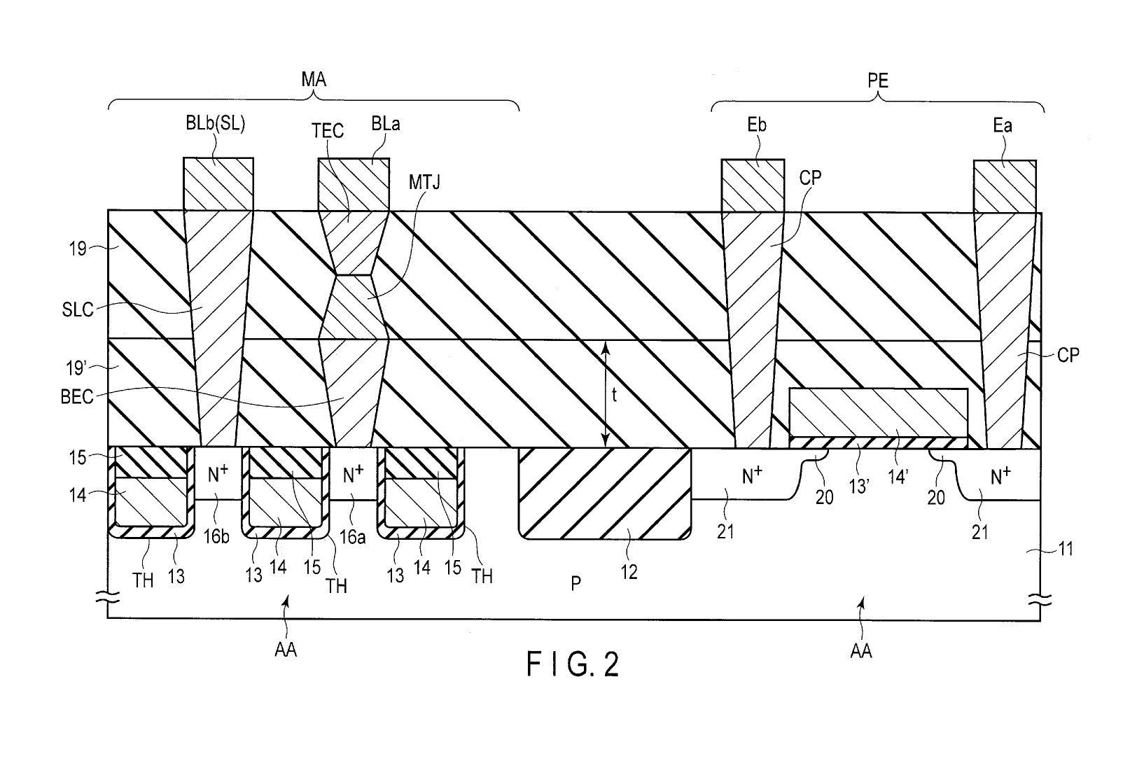

FIG. 2 shows the device structure as a comparative example.

In the comparative example, the peripheral circuit PE is a general planer FET. In this case, an interlayer insulating layer 19′ having a thickness t needs to be formed to cover the gate electrode 14′ since the gate electrode 14′ protrudes upwardly from the surface of the semiconductor substrate 11.

In other words, the magnetoresistive element MTJ needs to be formed on the interlayer insulating layer 19′, in the memory cell array MA.

Accordingly, a bottom electrode contact BEC is required and an aspect ratio of the source line contact SLC becomes large, in the memory cell array MA. In addition, an aspect ratio of the source/drain contact CP becomes large in the peripheral circuit PE. This is significant as the memory cell is microminiaturized.

Such a problem does not occur by adopting the device structure of the present embodiment even if the memory cell is microminiaturized. The device structure of the present embodiment is therefore effective for practical use of the novel memory such as MRAM.

### 2. Device Structure

### Memory Cell Array

An example further embodying the structure of the memory cell array shown in FIG. 1 will be hereinafter described.

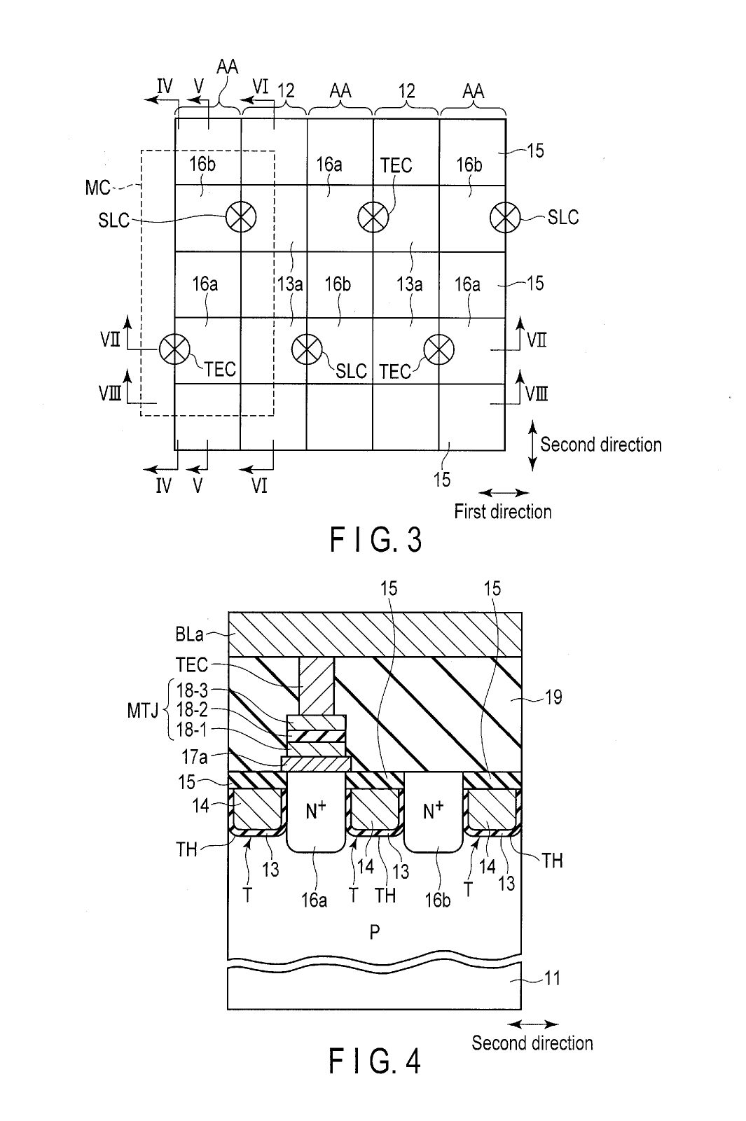

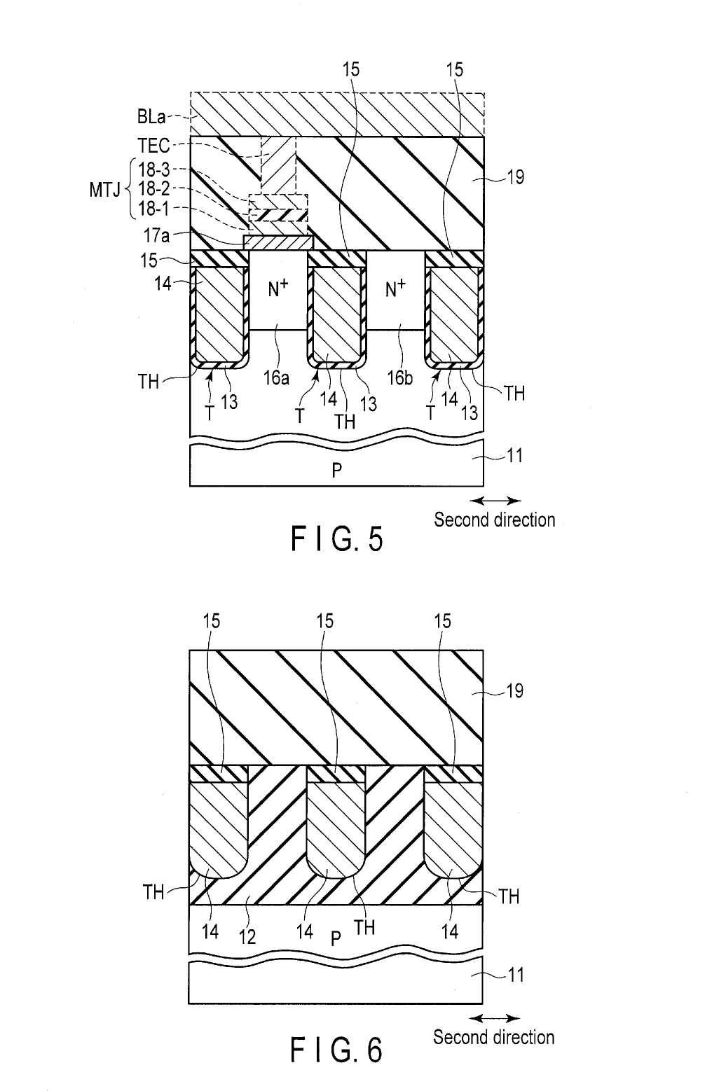

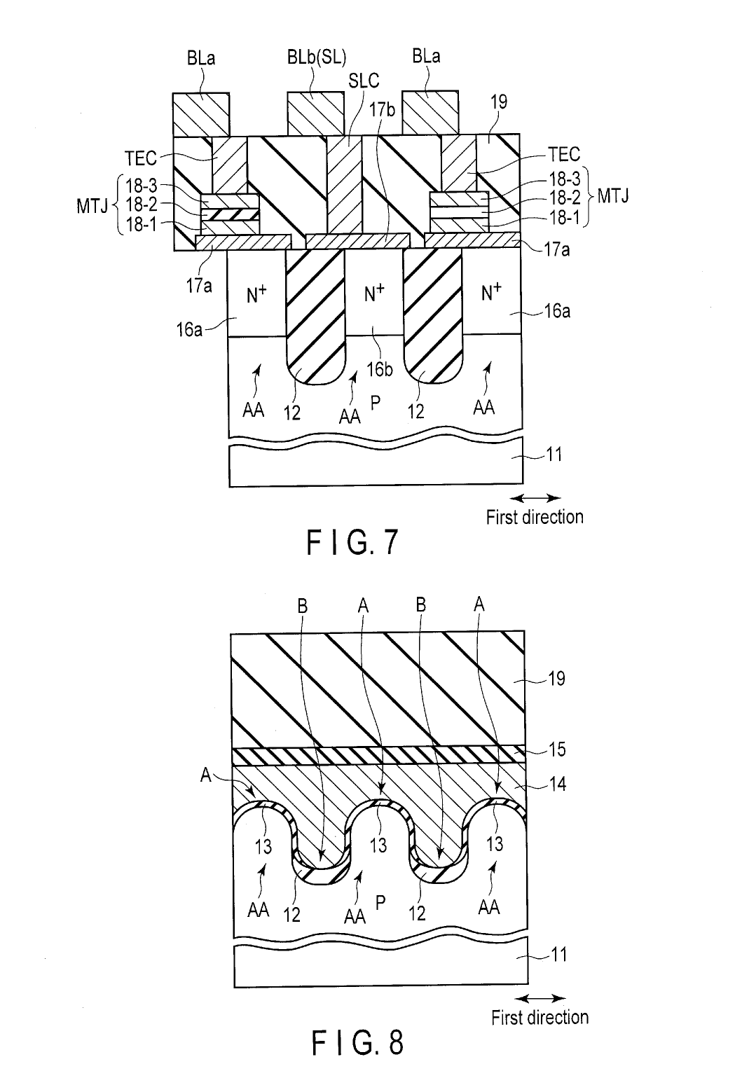

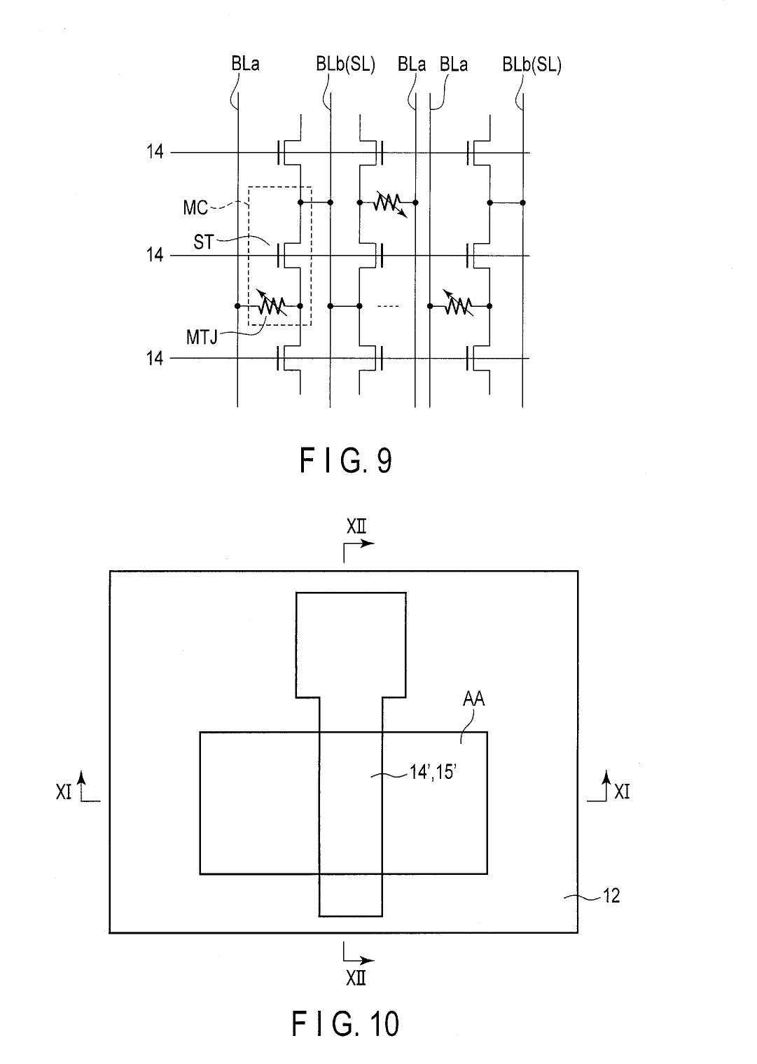

FIG. 3 is a plan view of the memory cell array. FIG. 4 is a cross-sectional view seen along line IV-IV in FIG. 2. FIG. 5 is a cross-sectional view seen along line V-V in FIG. 3. FIG. 6 is a cross-sectional view seen along line VI-VI in FIG. 3. FIG. 7 is a cross-sectional view seen along line VII-VII in FIG. 3. FIG. 8 is a cross-sectional view seen along line VIII-VIII in FIG. 3. FIG. 9 shows an equivalent circuit of the memory cell array shown in FIGS. 3 to 8.

In FIGS. 3 to 9, elements like or similar to the elements of the device structure shown in FIG. 1 are denoted by the same reference numbers as those in FIG. 1. In other words, characteristic portions of the present example alone are described, and detailed description of the same portions as those of the device structure shown in FIG. 1 is omitted.

In the memory cell array, the memory cell MC comprises the single select transistor (cell transistor) T and the single magnetoresistive element MTJ.

The trench TH is disposed in the semiconductor substrate 11, and extends in a first direction parallel to the upper surface of the semiconductor substrate 11. In addition, the trench TH comprises a first portion A having a first depth and a second portion B having a second depth larger than the first depth. In other words, in the trench TH, the active area AA is in a fin type so as to extend in a second direction which is parallel to the upper surface of the semiconductor surface 11 and which intersects with the first direction.

The gate insulating layer 13 and the gate electrode 14 are buried in the trench TH so as to straddle the fin-type active area AA. Furthermore, the upper surface of the gate electrode 14 is lower than the upper surfaces of the source/drain regions 16a and 16b. In other words, the select transistor T is in a saddle fin type.

The bit lines BLa and BLb extend in the second direction. The bit line BLb also functions as the source line SL at the reading.

The magnetoresistive element MTJ is disposed on the bottom electrode 17a on the source/drain region 16a. The magnetoresistive element MTJ comprises ferromagnetic layers 18-1 and 18-3, and a nonmagnetic insulating layer (tunnel barrier layer) 18-2 disposed between the ferromagnetic layers. The ferromagnetic layers 18-1 and 18-3 contain, for example, CoFeB. One of the ferromagnetic layers 18-1 and 18-3 is, for example, a memory layer having perpendicular and variable magnetization while the other is, for example, a reference layer having perpendicular and invariable magnetization. The nonmagnetic insulating layer 18-2 contains, for example, MgO.

In the present example, the top electrode contact TEC and the source line contact SLC are slightly displaced in the first direction with respect to the source/drain regions 16a and 16b. This improvement aims to make certain contact between the memory cell MC and the bit lines BLa and BLb even if the memory cell MC is microminiaturized.

### 3. First Example of Device Structure

### Peripheral Circuit

An example further embodying the structure of the peripheral circuit shown in FIG. 1 will be hereinafter described.

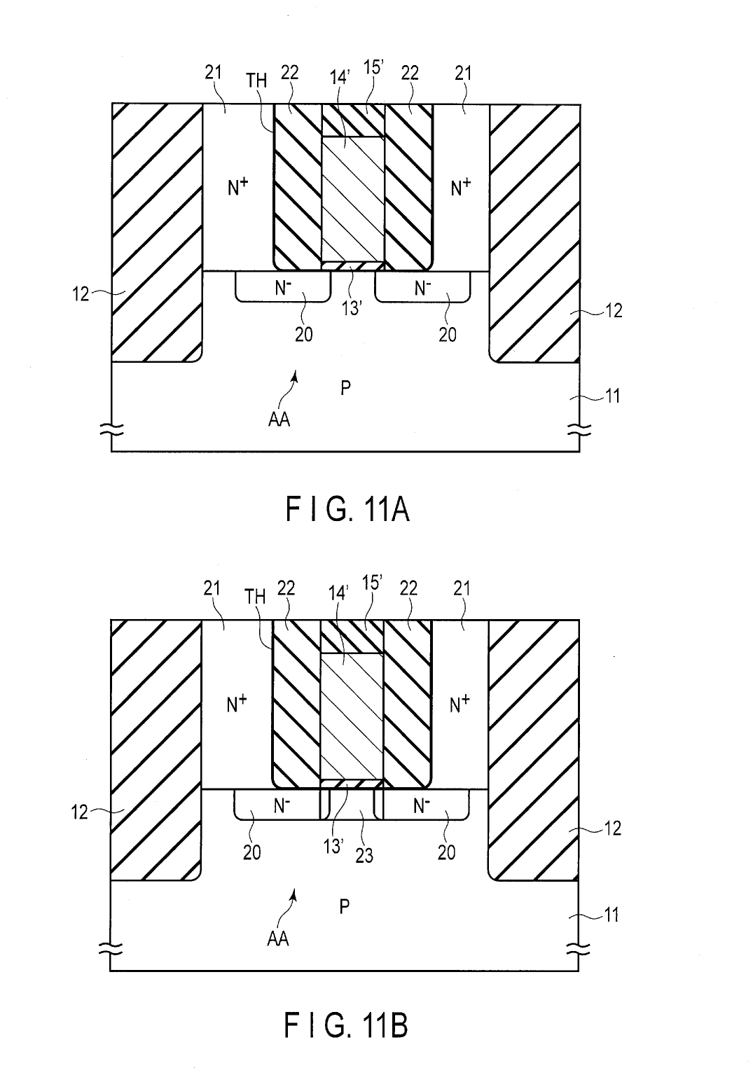

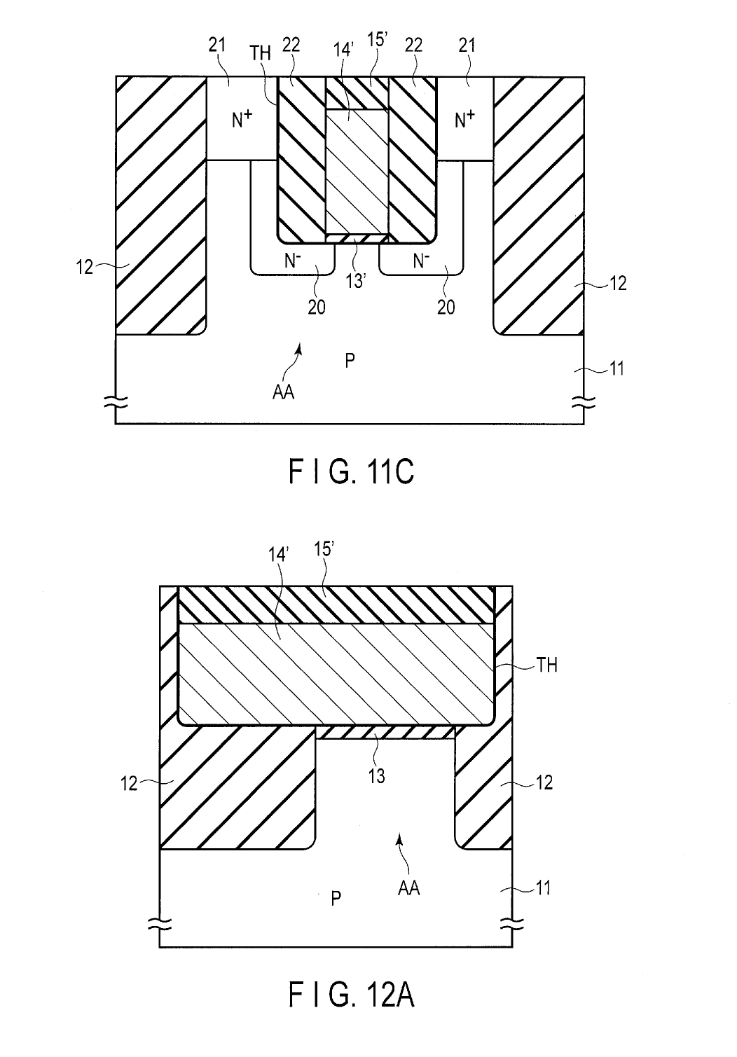

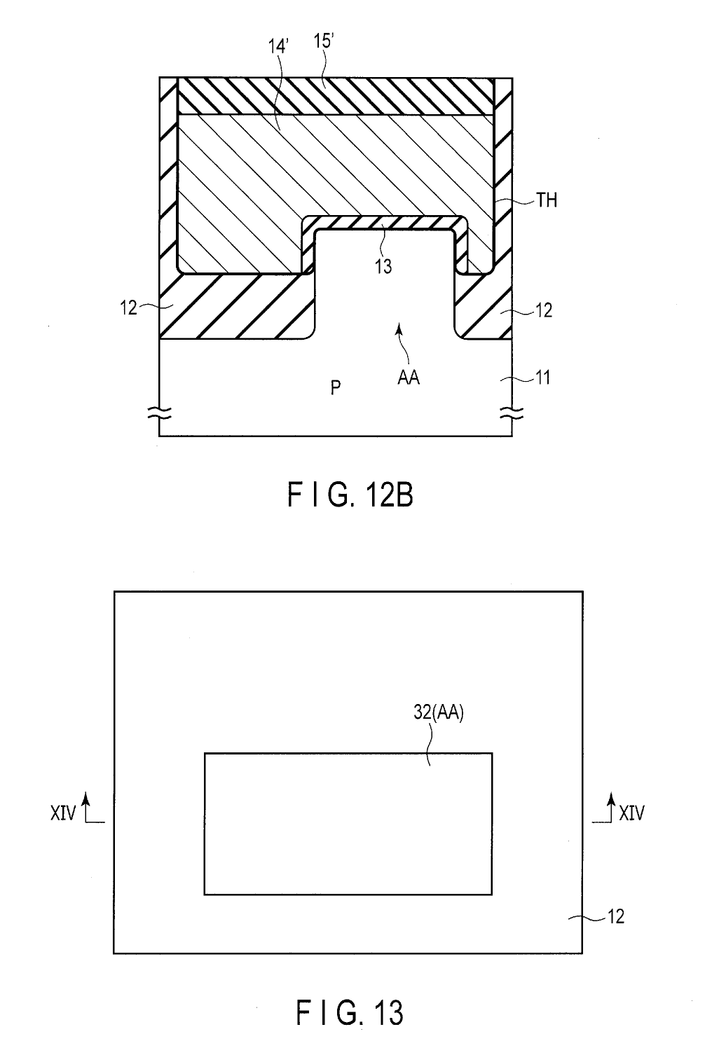

FIG. 10 is a plan view of the FET serving as a peripheral circuit. FIG. 11A, FIG. 11B and FIG. 11C are cross-sectional views seen along line XI-XI in FIG. 10. FIG. 12A and FIG. 12B are cross-sectional views seen along line XII-XII in FIG. 10.

In FIG. 10, FIG. 11A, FIG. 11B, FIG. 11C, FIG. 12A and FIG. 12B, elements like or similar to the elements of the device structure shown in FIG. 1 are denoted by the same reference numbers as those in FIG. 1. In other words, characteristic portions of the present example alone are described, and detailed description of the same portions as those of the device structure shown in FIG. 1 is omitted.

In the peripheral circuit, the FET is arranged in the semiconductor substrate 11 (active area AA) surrounded by the element isolation insulating layer 12.

The active area AA is shaped in a square and the gate electrode 14′ is arranged to straddle the active area AA, as seen from an upper side of the semiconductor substrate 11. The gate electrode 14′ has the upper surface lower than the upper surface of the source/drain region 21.

The semiconductor substrate 11 disposed immediately under the gate electrode 14′ functions as a channel of the FET. In addition, an edge at a lower portion of the gate sidewall insulating layer 22 (i.e., an edge between the bottom surface and the side surface of the trench TH) is rounded from the viewpoint of the channel mobility.

The extension region 20 is arranged inside the semiconductor substrate 11 adjacent to the bottom surface of the trench TH. The source/drain region 21 is arranged inside the semiconductor substrate 11 adjacent to the side surface of the trench TH.

The structure shown in FIG. 11A corresponds to that in FIG. 1. A channel between two extension regions 20 may be a compound semiconductor layer 23, for example, SiGe as shown in FIG. 11B. Furthermore, the extension region 20 may be arranged inside the semiconductor substrate 11 adjacent to the side surface of the trench TH as shown in FIG. 11C.

The gate electrode 14′ may cover the upper surface alone of the fin-type active area AA as shown in FIG. 12A or may cover the upper surface and the side surface of the fin-type active area AA as shown in FIG. 12B. The latter structure is called a saddle fin type.

### 4. Method of Manufacturing Device Structure

### First Example

Next, an example of a method of manufacturing the peripheral circuit will be described with reference to FIGS. 13 to 30.

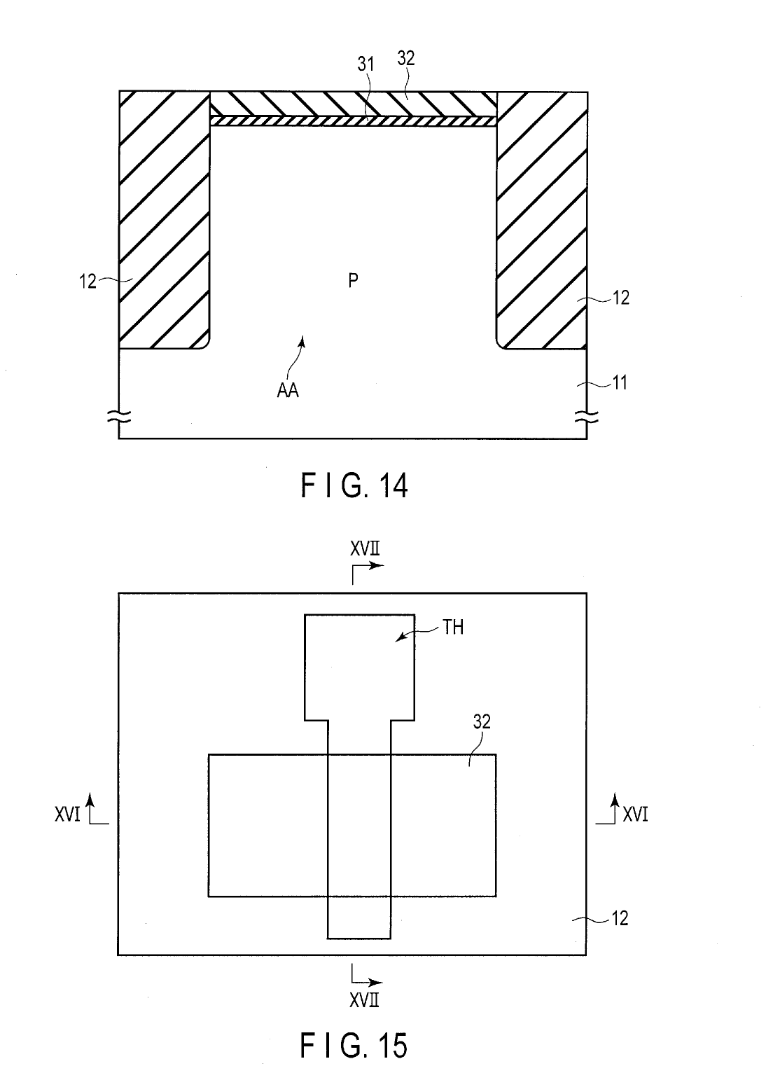

First, a silicon oxide layer 31 and a silicon nitride layer 32 are formed on the semiconductor substrate (silicon substrate) 11 as shown in FIG. 13 and FIG. 14. The silicon nitride layer 32 is patterned by photo engraving process (PEP) and reactive ion etching (RIE). After that, a trench is formed inside the semiconductor substrate 11 by the RIE using the silicon nitride layer 32 as a mask.

In addition, the trench is filled with, for example, the silicon oxide layer by chemical vapor deposition (CVD) and chemical mechanical polishing (CMP). The element isolation insulating layer 12 having the shallow trench isolation (STI) structure is thereby formed inside the semiconductor substrate 11. The semiconductor substrate 11 surrounded by the element isolation insulating layer 12 functions as the active area AA.

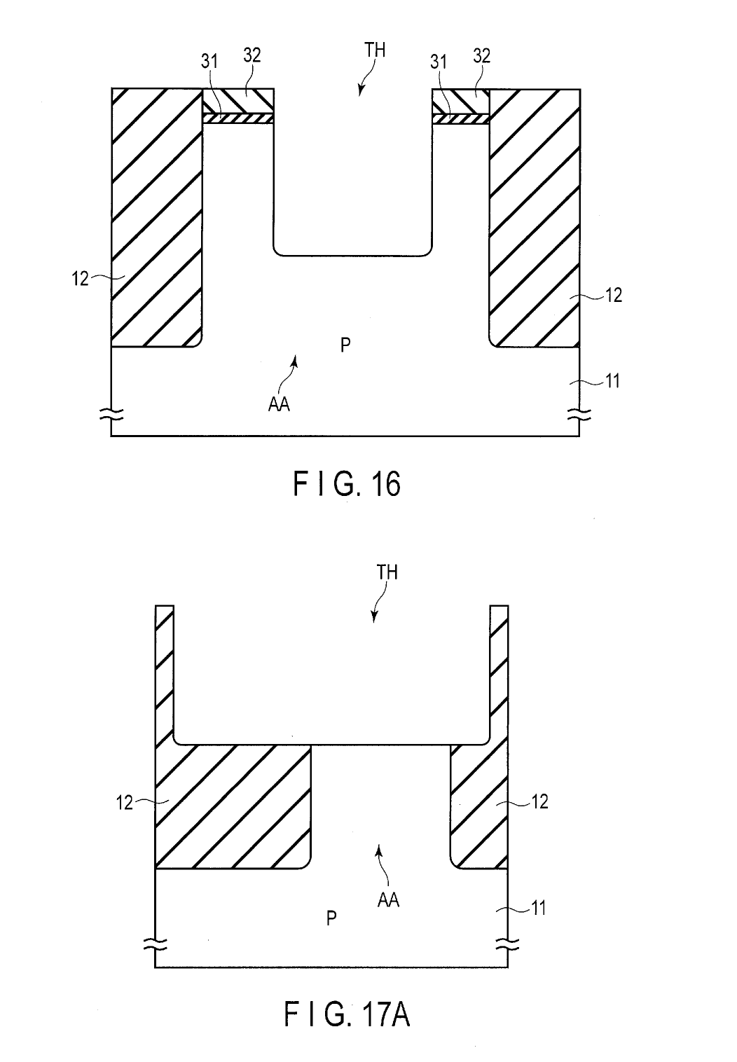

Next, the trench TH is formed in the active area AA by the RIE using a mask layer (for example, a resist layer) as a mask, as shown in FIG. 15 and FIG. 16. The bottom surface of the trench TH should preferably be arranged at a position upper than the bottom surface of the element isolation insulating layer 12.

Two types of trenches TH as described below can be formed according to an etching process.

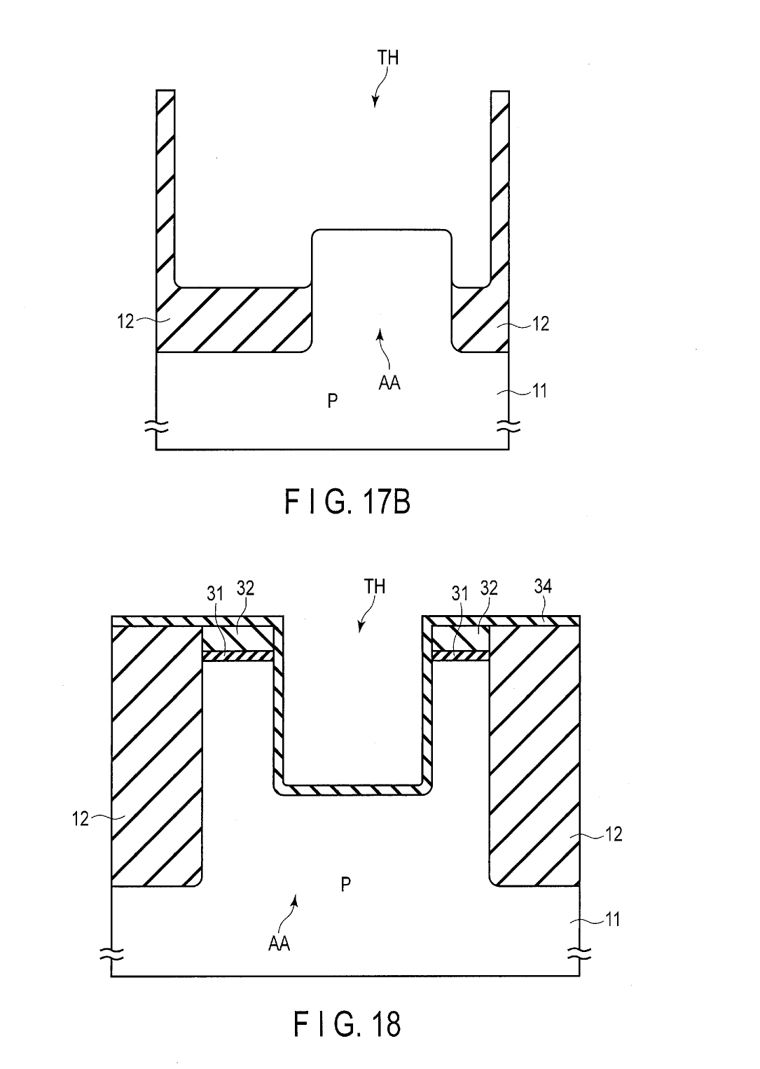

For example, if etching is executed under a condition for flattening the bottom surface of the trench TH, the upper surface alone in the active area AA is exposed inside the trench TH, as shown in FIG. 17A. In addition, if etching is executed under a condition for causing the bottom surface of the trench TH to be uneven, the upper surface and the side surface in the active area AA are exposed inside the trench TH, as shown in FIG. 17B. If the latter process is adopted, the active area AA has the fin structure.

The process in FIG. 17A corresponds to the structure in FIG. 12A, and the process in FIG. 17B corresponds to the structure in FIG. 12B.

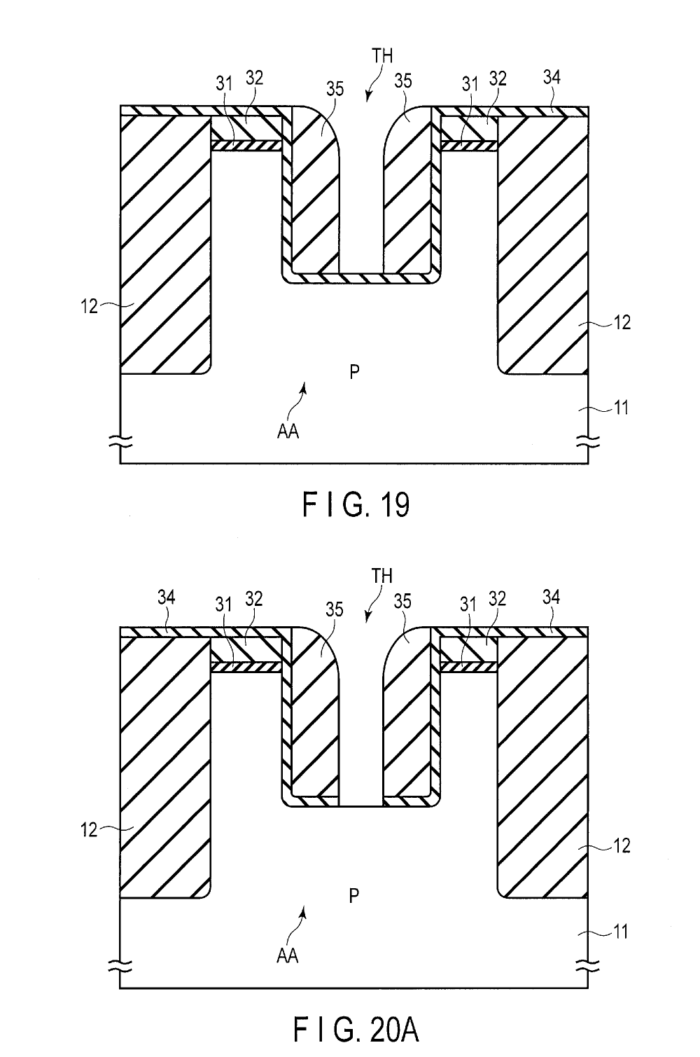

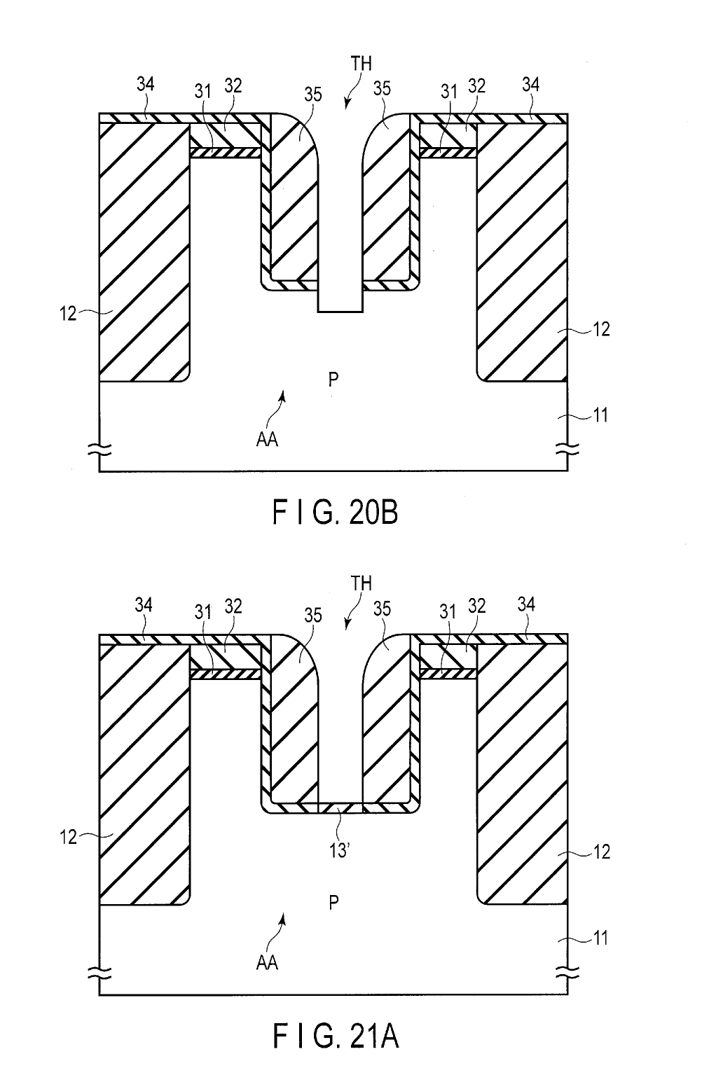

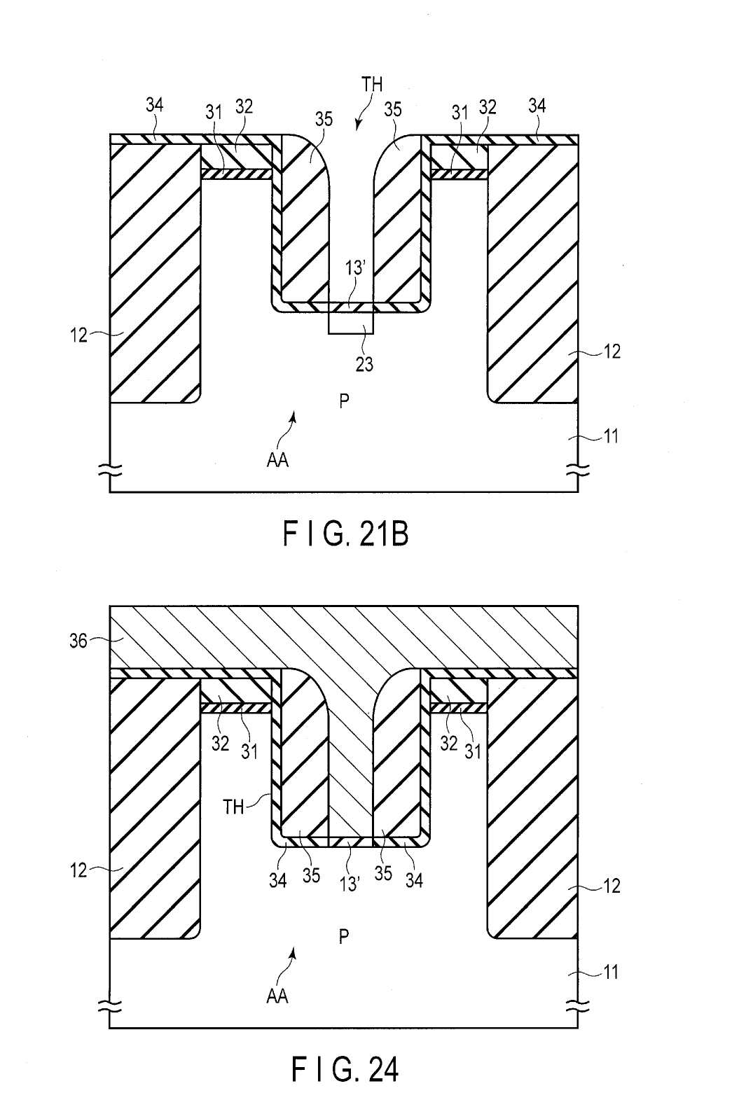

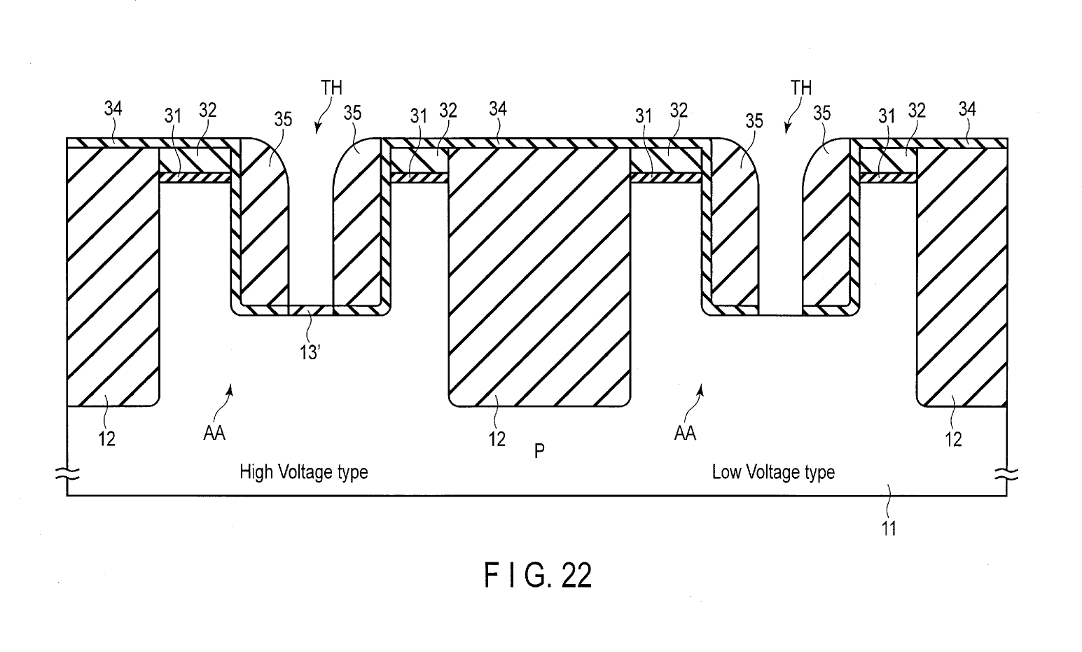

Next, a silicon oxide layer 34 for covering inner surfaces (bottom surface and side surface) of the trench TH is formed by the CVD, as shown in FIG. 18. Subsequently, the gate sidewall insulating layer 35 is formed on the side surface of the trench TH as shown in FIG. 19. The gate sidewall insulating layer 35 is, for example, a silicon nitride layer and can be formed by a combination of the CVD and the RIE.

Next, the silicon oxide layer 34 on the bottom surface of the trench TH is removed by wet etching using the gate sidewall insulating layer 35 as a mask, as shown in FIG. 20A. Subsequently, the gate insulating layer (silicon oxide layer) 13′ is formed on the bottom surface of the trench TH by thermal oxidation, as shown in FIG. 21A.

In addition, the gate insulating layer 13′ can also be formed by depositing a high-k material on the bottom surface of the trench TH.

The silicon oxide layer 34 on the bottom surface of the trench TH can be removed and a part of the semiconductor substrate 11 can also be removed, by using the gate sidewall insulating layer 35 as a mask, as shown in FIG. 20B. In this case, the compound semiconductor layer (SiGe layer) 23 is formed in a recess portion between the gate sidewall insulating layers 35 by epitaxial growth, as shown in FIG. 21B. In addition, the gate insulating layer (for example, high-k material) 13′ is formed on the compound semiconductor layer 23.

The process in FIG. 20A and FIG. 21A corresponds to the structure in FIG. 11A, and the process in FIG. 20B and FIG. 21B corresponds to the structure in FIG. 11B.

In addition, after forming the gate insulating layer 13′ by thermal oxidation, the gate insulating layer 13′ of a low voltage type FET can be selectively removed as shown in FIG. 22 and then the gate insulating layer 13′ can also be formed by thermal oxidation as shown in FIG. 23. In this case, the thickness of the gate insulating layer 13′ of a high voltage type FET is larger than the thickness of the gate insulating layer 13′ of the low voltage type FET.

If this process is adopted, a plurality of gate insulating layers 13′ having different thicknesses can be formed in the single semiconductor substrate 11.

Next, a polysilicon layer 36 to be embedded in the trench TH is formed by the CVD, as shown in FIG. 24. In addition, N-type impurities (P, As, etc.) are implanted in the polysilicon layer 36 by ion implantation, and the polysilicon layer 36 is subjected to annealing. The polysilicon layer 36 thereby becomes conductive.

Next, a conductive polysilicon layer 36 is left in the trench TH by the CMP or RIE, as shown in FIG. 25. As a result, the conductive polysilicon layer 36 is capable of functioning as the gate electrode 14′. The upper surface of the gate electrode 14′ should preferably be lower than the upper surface of the semiconductor substrate 11 outside the trench TH.

After that, the structure shown in FIG. 26 can be obtained by removing the gate sidewall insulating layer 35.

Next, for example, N-type impurities (P, As, etc.) are implanted by ion implantation using the gate electrode 14′ as a mask, as shown in FIG. 27A. As a result, the extension region (impurity region) 20 is formed inside the semiconductor substrate 11 adjacent to the bottom surface of the trench TH.

If the ion implantation is executed in a direction oblique about an axis perpendicular to the upper surface of the semiconductor substrate 11, the extension region 20 can also be arranged in the semiconductor substrate 11 adjacent to the side surface of the trench TH, as shown in FIG. 27B.

The process in FIG. 27B corresponds to the structure in FIG. 11C.

Next, an insulating layer 37 to be embedded in the trench TH is formed by the CVD, as shown in FIG. 28. The insulating layer 37 is, for example, a silicon oxide layer, which functions as a new gate sidewall insulating layer. The insulating layer 37 may contain a low-k material. The insulating layer 37 is left in the trench TH by the CMP, as shown in FIG. 29.

Finally, for example, N-type impurities (P, As, etc.) are implanted in the semiconductor substrate 11 outside the trench TH by ion implantation, as shown in FIG. 30. As a result, the source/drain region (impurity region) 21 is formed inside the semiconductor substrate 11 adjacent to the side surface of the trench TH.

Conditions for ion implantation are set such that an impurity concentration of the source/drain region 21 is higher than that of the extension region 20.

The device structure (first example) is completed in the above-described manufacturing method.

### 5. Second Example of Device Structure

### Peripheral Circuit

An example further embodying the structure of the peripheral circuit shown in FIG. 1 will be hereinafter described.

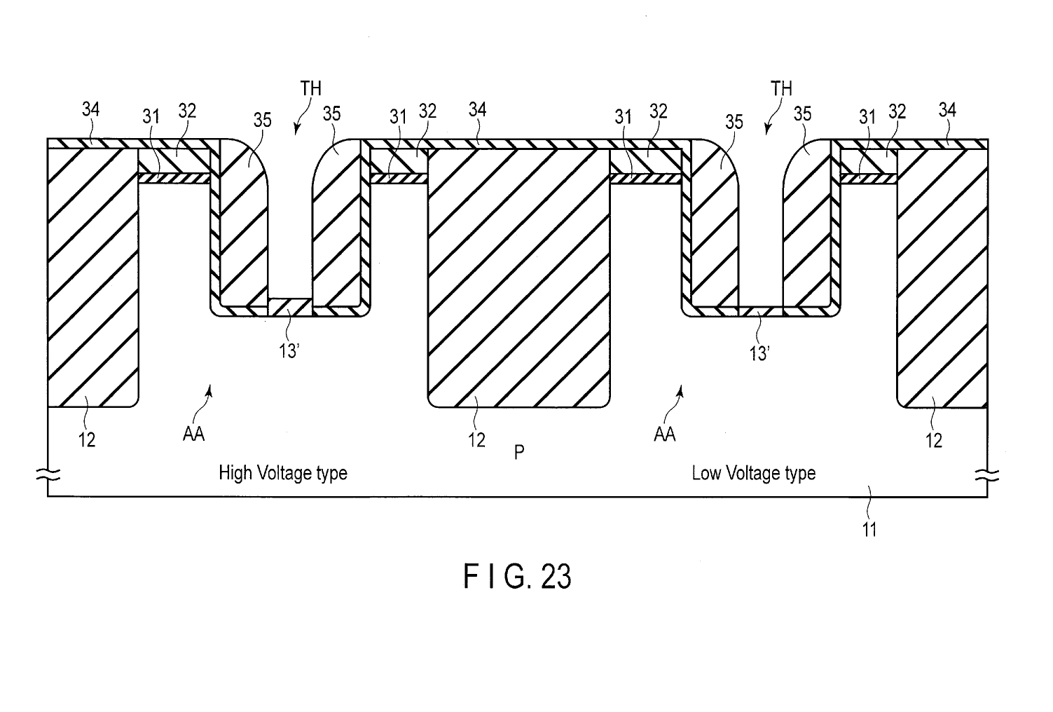

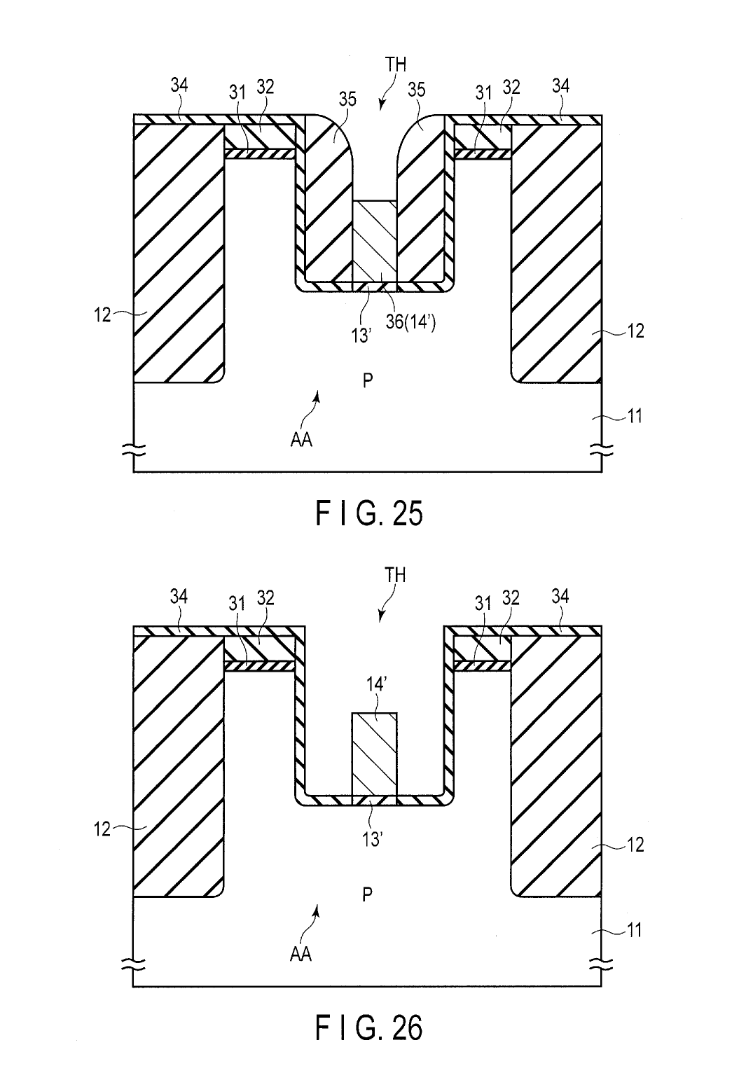

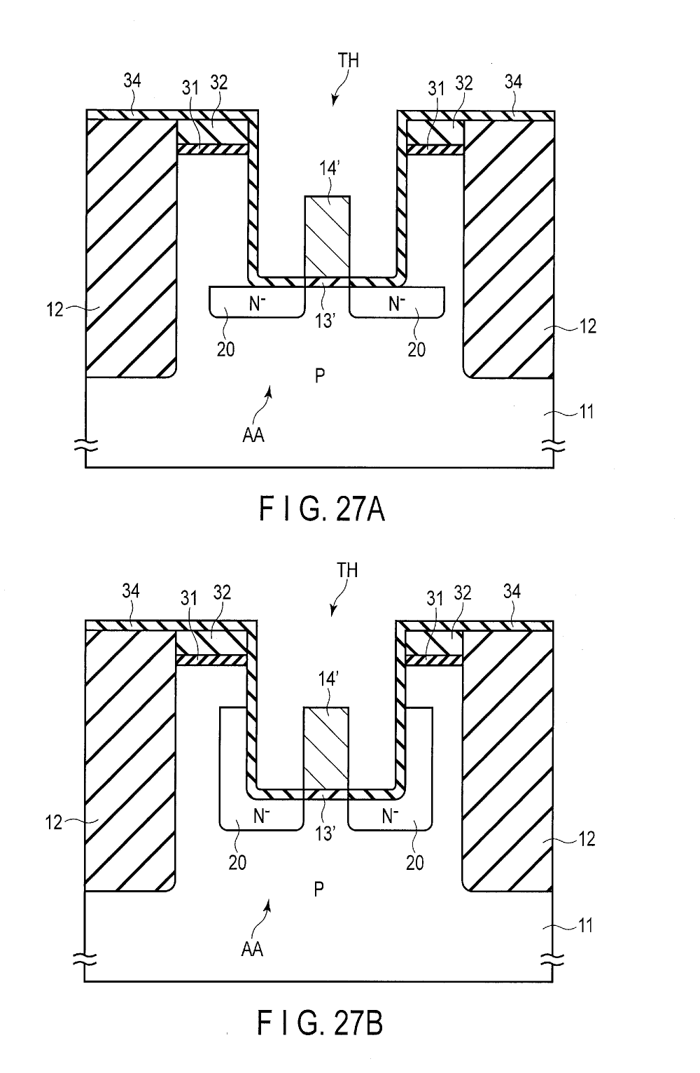

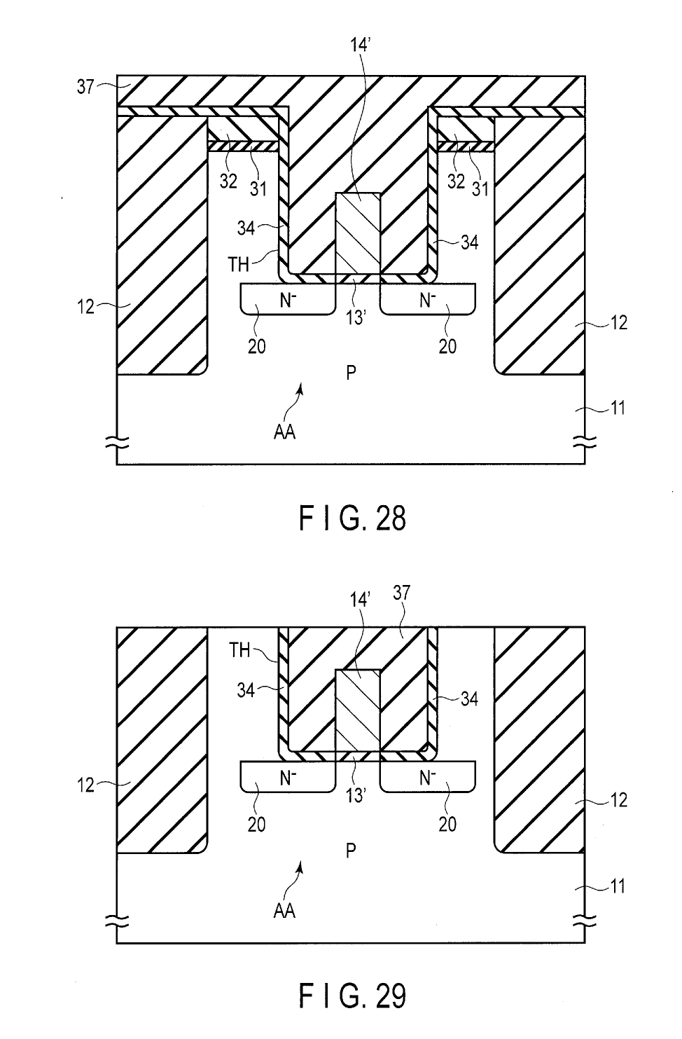

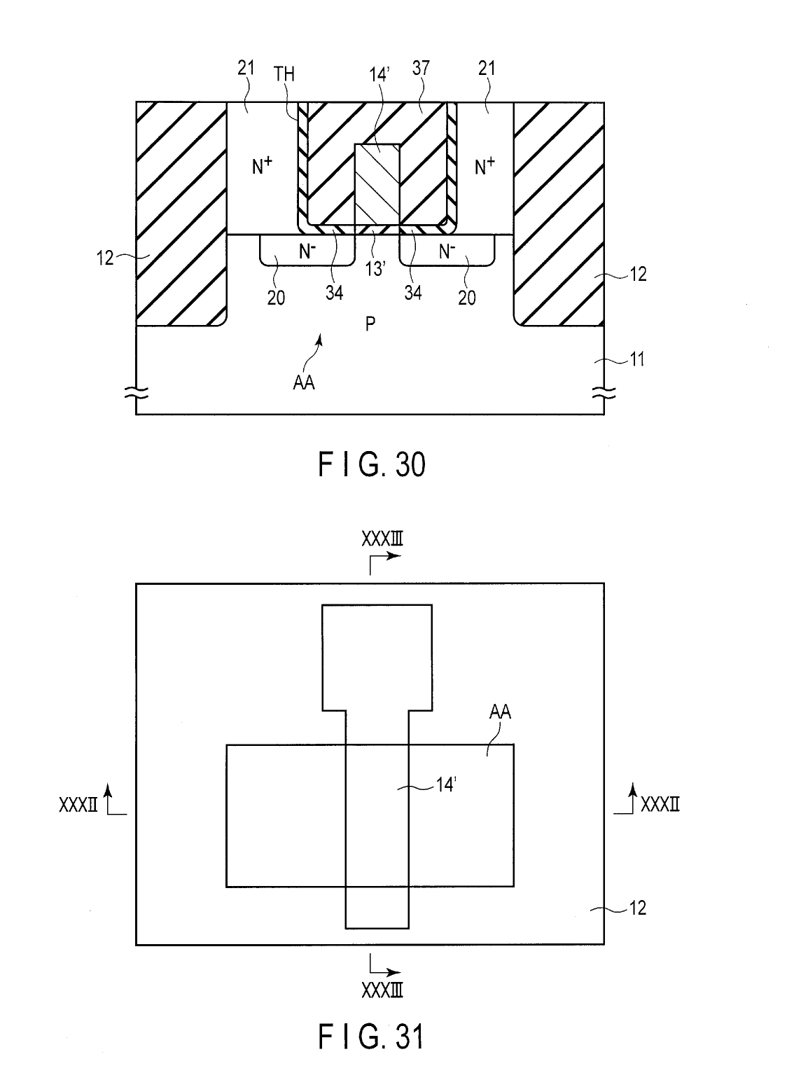

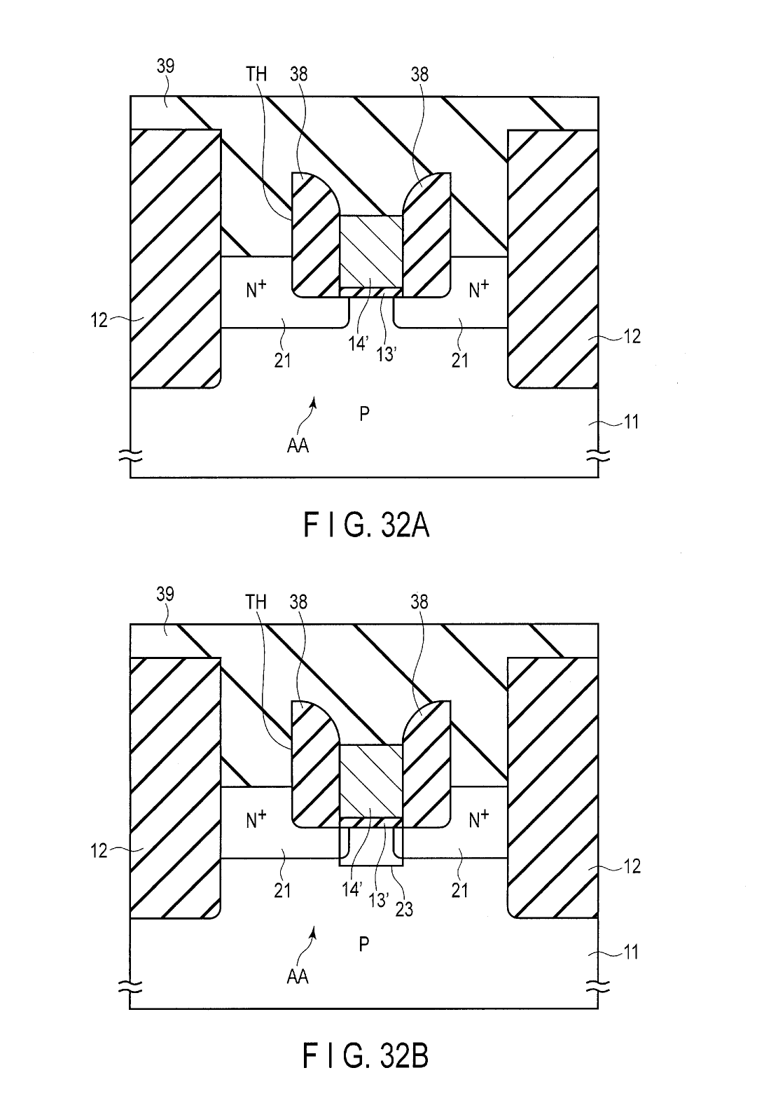

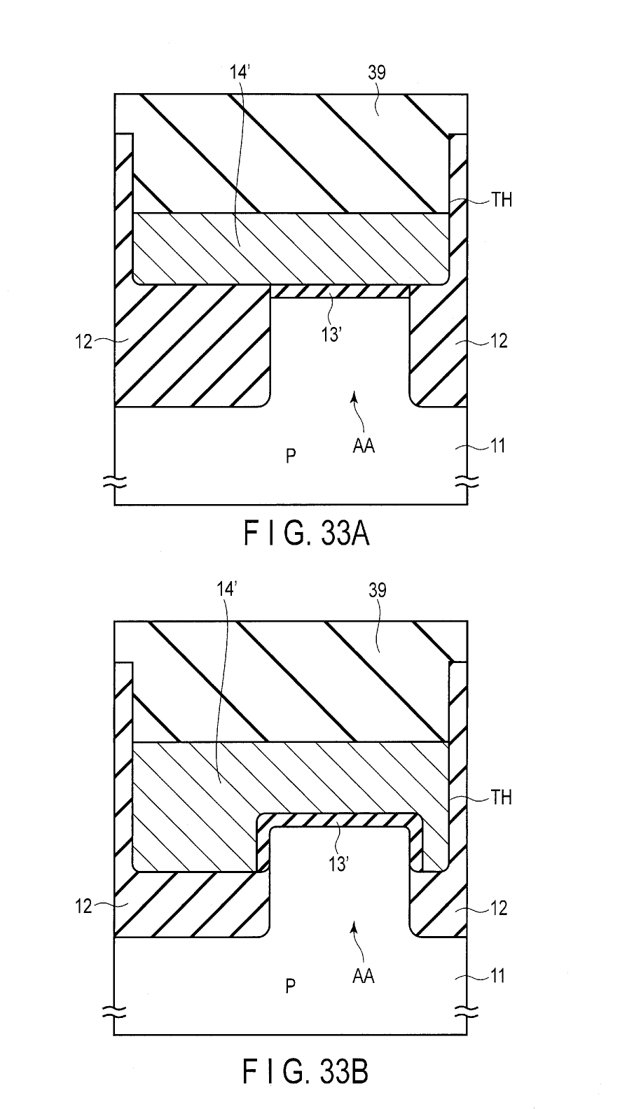

FIG. 31 is a plan view of the FET serving as a peripheral circuit. FIG. 32A and FIG. 32B are cross-sectional views seen along line XXXII-XXXII in FIG. 31. FIG. 33A and FIG. 33B are cross-sectional views seen along line XXXIII-XXXIII in FIG. 31.

In FIG. 31, FIG. 32A, FIG. 32B, FIG. 33A and FIG. 33B, elements like or similar to the elements of the device structure shown in FIG. 1 are denoted by the same reference numbers as those in FIG. 1. In other words, characteristic portions of the present example alone are described, and detailed description of the same portions as those of the device structure shown in FIG. 1 is omitted.

In the peripheral circuit, the FET is arranged in the semiconductor substrate 11 (active area AA) surrounded by the element isolation insulating layer 12.

The active area AA is shaped in a square and the gate electrode 14′ is arranged to straddle the active area AA, as seen from an upper side of the semiconductor substrate 11. The gate electrode 14′ has the upper surface lower than the upper surface of the element isolation insulating layer 12.

The semiconductor substrate 11 disposed immediately under the gate electrode 14′ functions as the channel of the FET. In addition, an edge at a lower portion of a gate sidewall insulating layer 38 (i.e., an edge between the bottom surface and the side surface of the trench TH) is rounded from the viewpoint of improvement of the channel mobility.

The source/drain region 21 is arranged inside the semiconductor substrate 11 adjacent to the side surface and the bottom surface of the trench TH. The upper surface of the source/drain region 21 is lower than the upper surface of the gate electrode 14′ and higher than the lower surface of the gate electrode 14′.

A channel between two source/drain regions 21 may be a semiconductor substrate (Si layer) 11 as shown in FIG. 32A or may be a compound semiconductor layer 23, for example, SiGe as shown in FIG. 32B. The gate electrode 14′ may cover the upper surface alone of the active area AA as shown in FIG. 33A or may cover the upper surface and the side surface of the active area AA as shown in FIG. 33B.

### 6. Method of Manufacturing Device Structure

### Second Example

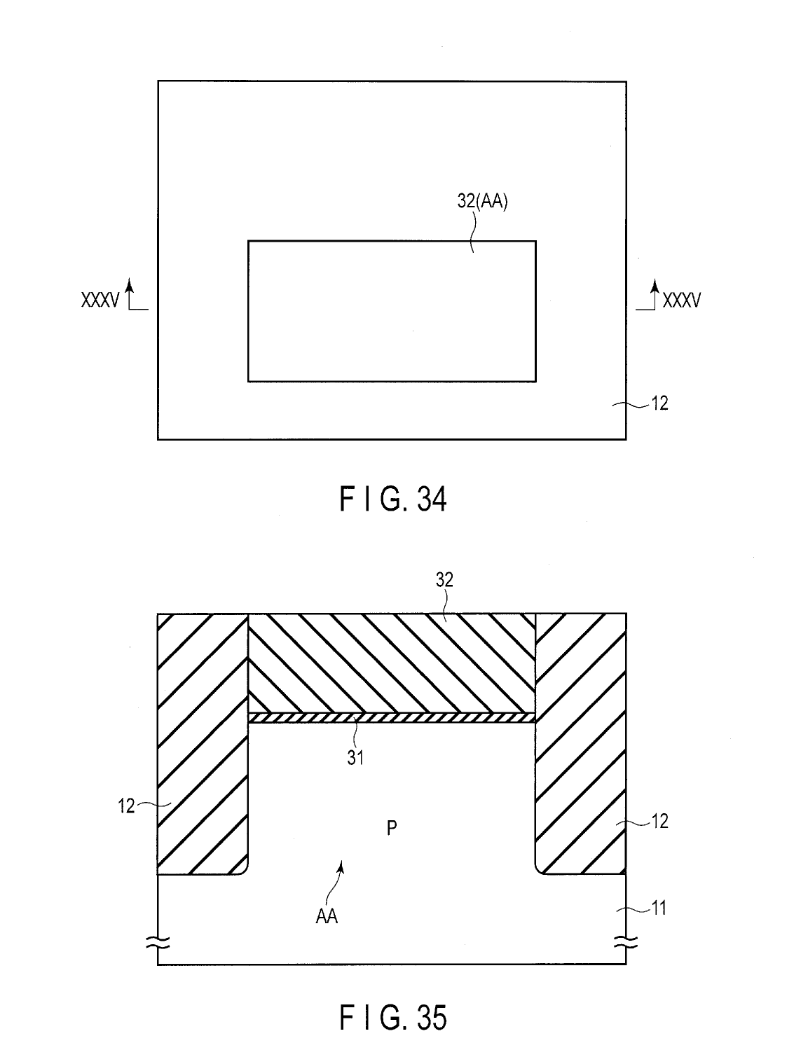

Next, a method of manufacturing the peripheral circuit will be described with reference to FIGS. 34 to 49.

First, the silicon oxide layer 31 and the silicon nitride layer 32 are formed on the semiconductor substrate (silicon substrate) 11 as shown in FIG. 34 and FIG. 35. The silicon nitride layer 32 is patterned by the PEP and the RIE. After that, a trench is formed inside the semiconductor substrate 11 by the RIE using the silicon nitride layer 32 as a mask.

In addition, the trench is filled with, for example, the silicon oxide layer by the CVD and the CMP. The element isolation insulating layer 12 having the STI structure is thereby formed inside the semiconductor substrate 11. The semiconductor substrate 11 surrounded by the element isolation insulating layer 12 functions as the active area AA.

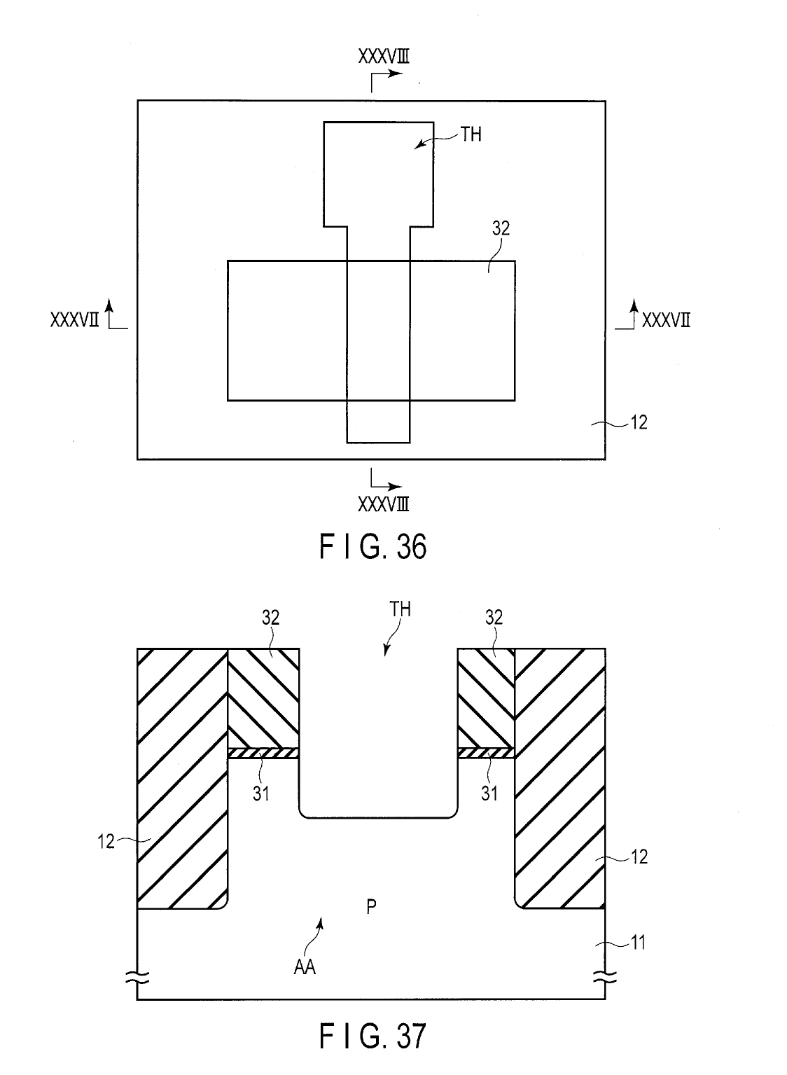

Next, the trench TH is formed in the active area AA by the RIE using a mask layer (for example, a resist layer) as a mask, as shown in FIG. 36 and FIG. 37. The bottom surface of the trench TH should preferably be arranged at a position upper than the bottom surface of the element isolation insulating layer 12.

Two types of trenches TH as described below can be formed according to an etching process.

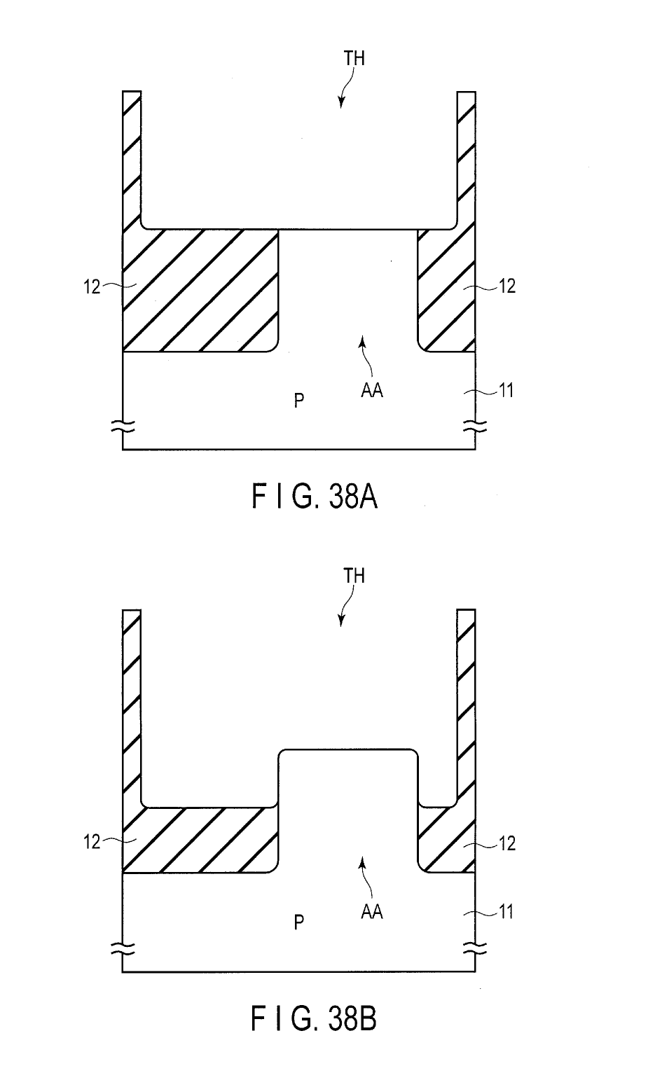

For example, if etching is executed under a condition for flattening the bottom surface of the trench TH, the upper surface alone in the active area AA is exposed inside the trench TH, as shown in FIG. 38A. In addition, if etching is executed under a condition for causing the bottom surface of the trench TH to be uneven, the upper surface and the side surface in the active area AA are exposed inside the trench TH, as shown in FIG. 38B. If the latter process is adopted, the active area AA has the fin structure.

The process in FIG. 38A corresponds to the structure in FIG. 33A, and the process in FIG. 38B corresponds to the structure in FIG. 33B.

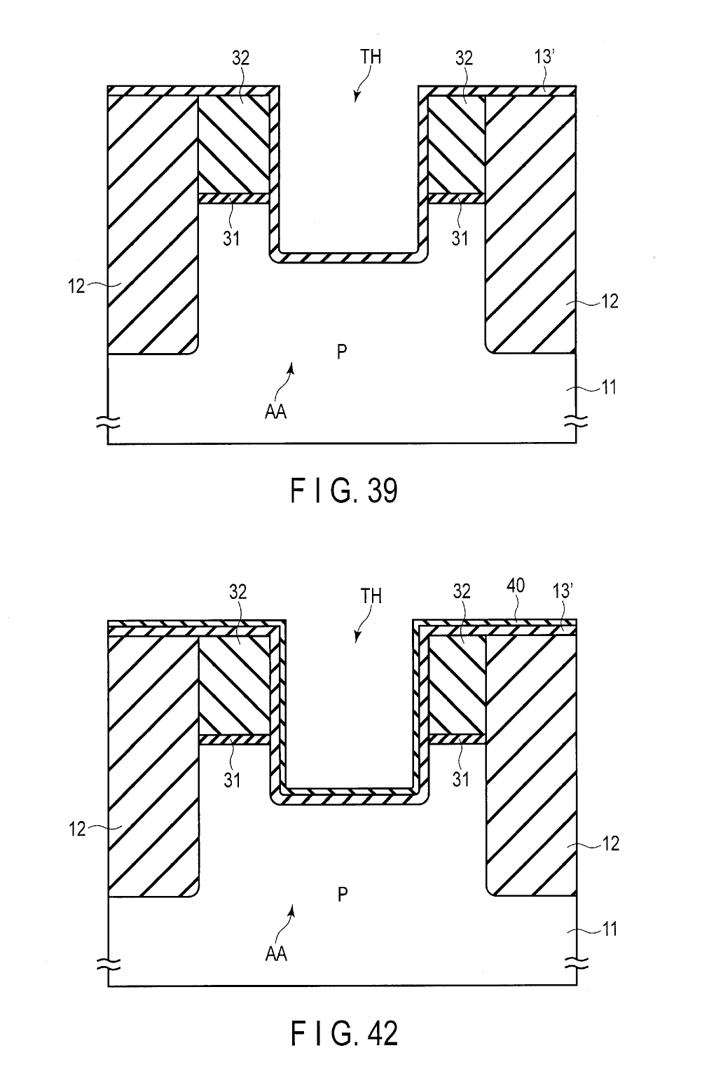

Next, the gate insulating layer 13′ for covering inner surfaces (bottom surface and side surface) of the trench TH is formed as shown in FIG. 39. The gate insulating layer 13′ may contain a high-k material.

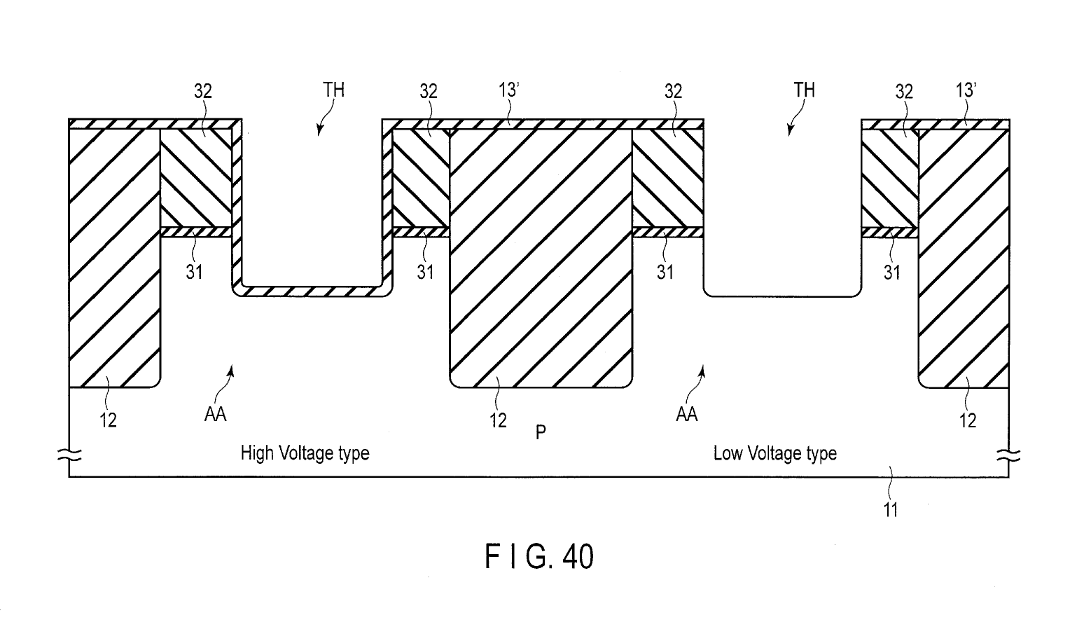

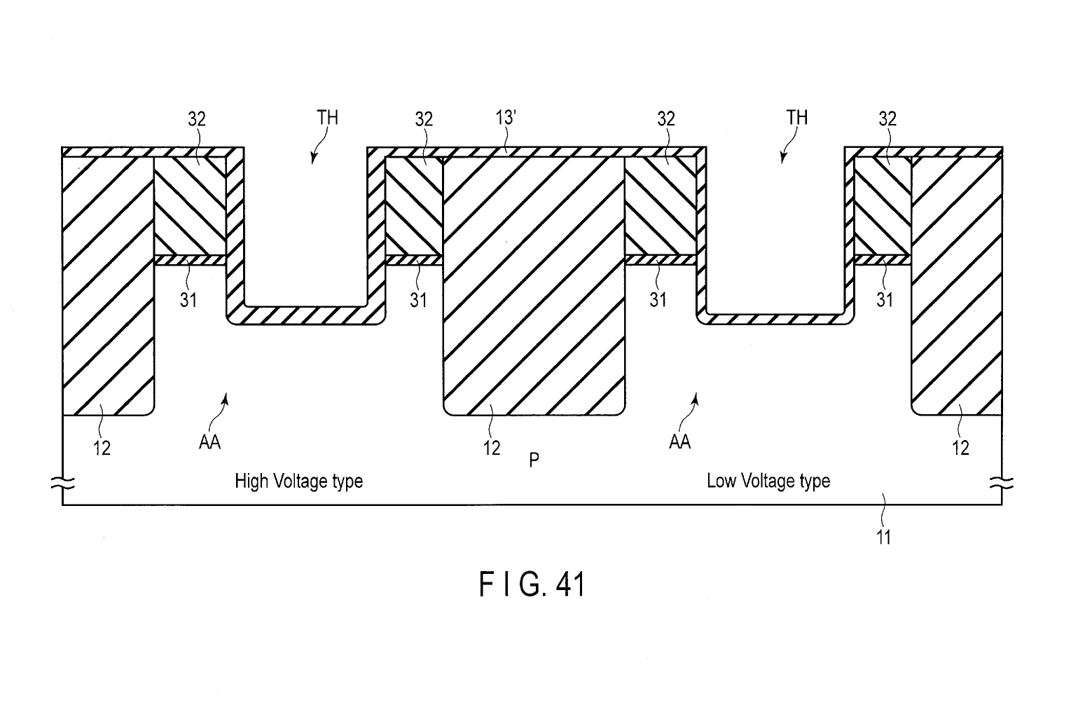

In addition, after forming the gate insulating layer 13′ by thermal oxidation, the gate insulating layer 13′ of a low voltage type FET can be selectively removed as shown in FIG. 40 and then the gate insulating layer 13′ can also be formed by thermal oxidation as shown in FIG. 41. In this case, the thickness of the gate insulating layer 13′ of a high voltage type FET is larger than the thickness of the gate insulating layer 13′ of the low voltage type FET.

If this process is adopted, a plurality of gate insulating layers 13′ having different thicknesses can be formed in the single semiconductor substrate 11.

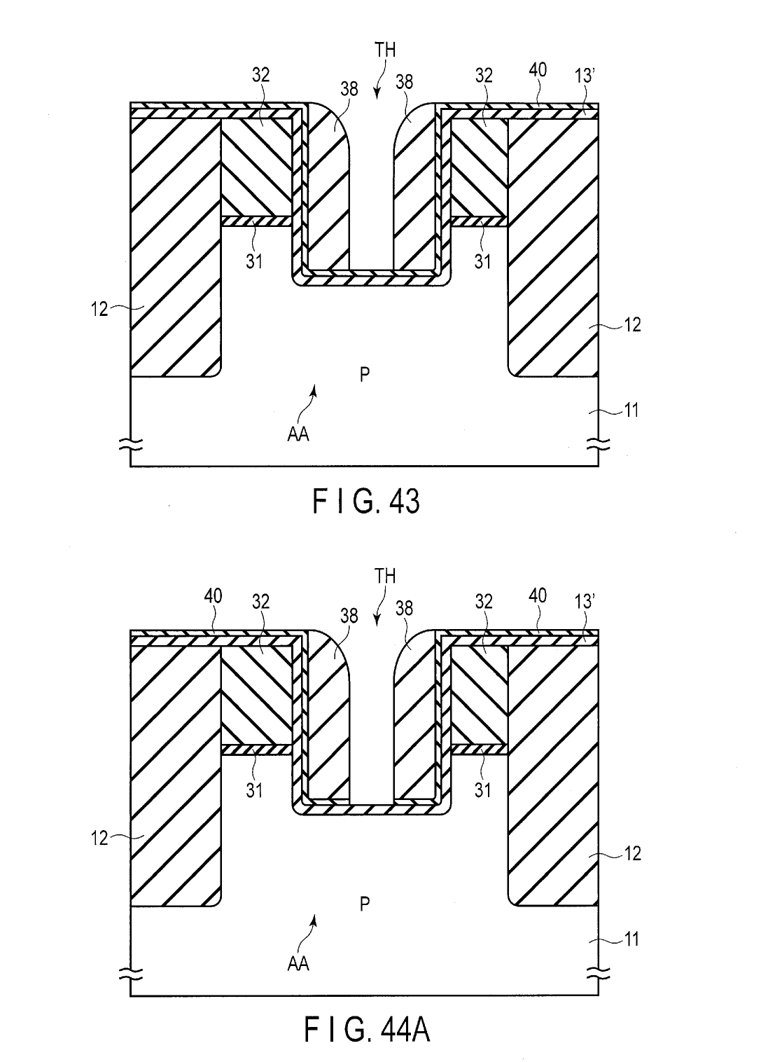

Next, a silicon nitride layer 40 is formed on the gate insulating layer 13′ by the CVD as shown in FIG. 42. Subsequently, the gate sidewall insulating layer 38 is formed on the side surface of the trench TH as shown in FIG. 43. The gate sidewall insulating layer 38 is, for example, a silicon oxide layer and can be formed by a combination of the CVD and the RIE. The gate sidewall insulating layer 38 may contain a low-k material.

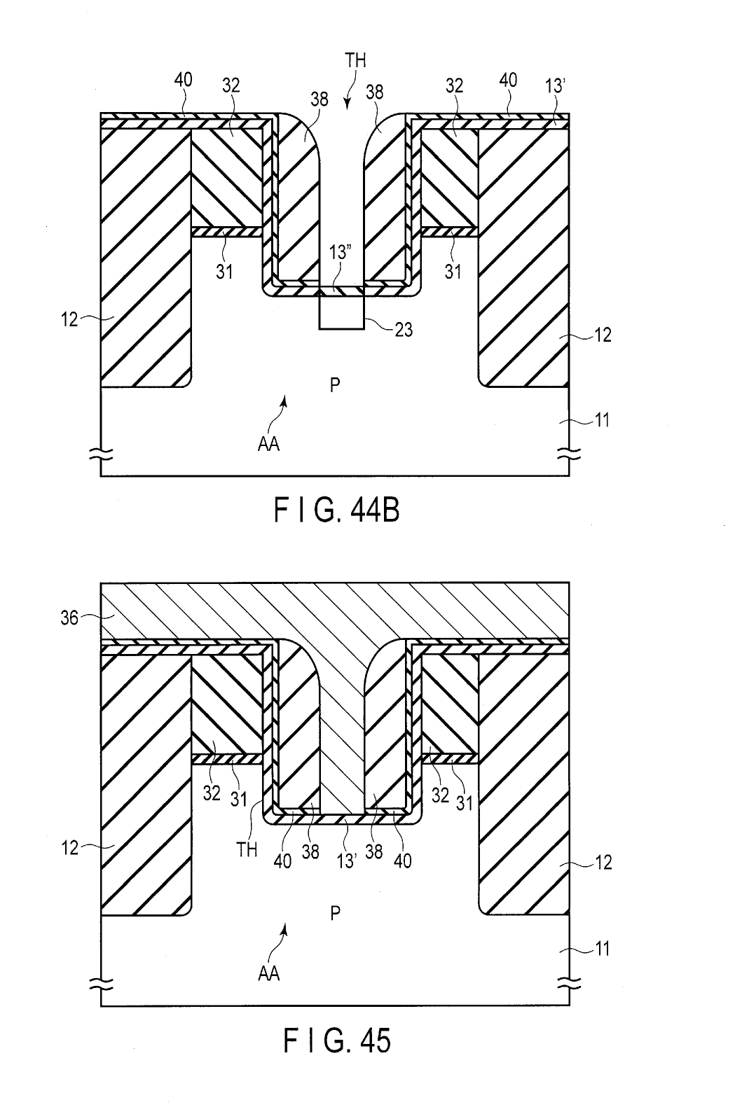

Next, the silicon nitride layer 40 on the bottom surface of the trench TH is removed by wet etching using the gate sidewall insulating layer 38 as a mask, as shown in FIG. 44A.

The silicon nitride layer 40 on the bottom surface of the trench TH can be removed, and a part of the gate insulating layer 13′ and a part of the semiconductor substrate 11 can also be removed, by using the gate sidewall insulating layer 38 as a mask, as shown in FIG. 44B. In this case, the compound semiconductor layer (SiGe layer) 23 is formed in a recess portion between the gate sidewall insulating layers 38 by epitaxial growth. In addition, the gate insulating layer (for example, high-k material) 13″ is formed on the compound semiconductor layer 23.

Next, the polysilicon layer 36 to be embedded in the trench TH is formed by the CVD, as shown in FIG. 45. In addition, N-type impurities (P, As, etc.) are implanted in the polysilicon layer 36 by ion implantation, and the polysilicon layer 36 is subjected to annealing. The polysilicon layer 36 thereby becomes conductive.

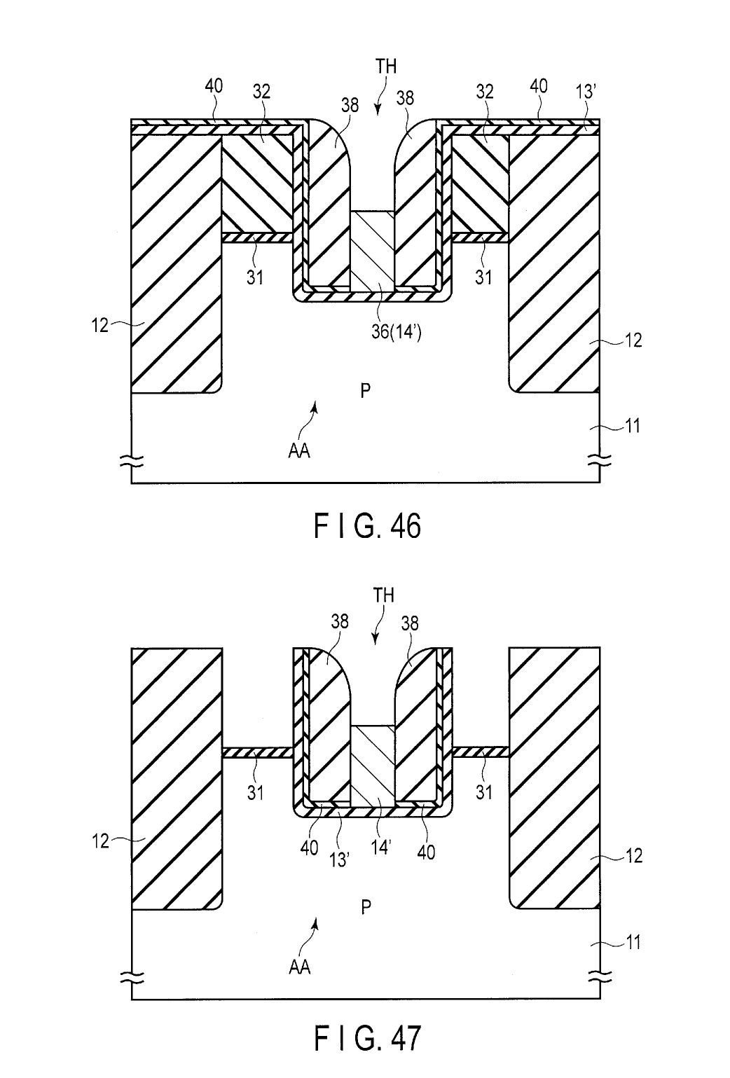

Next, the conductive polysilicon layer 36 is left in the trench TH by the CMP or RIE, as shown in FIG. 46. As a result, the conductive polysilicon layer 36 is capable of functioning as the gate electrode 14′. The upper surface of the gate electrode 14′ should preferably be lower than the upper surface of the element isolation insulating layer 12.

After that, the structure shown in FIG. 47 can be obtained by removing the silicon nitride layer 32.

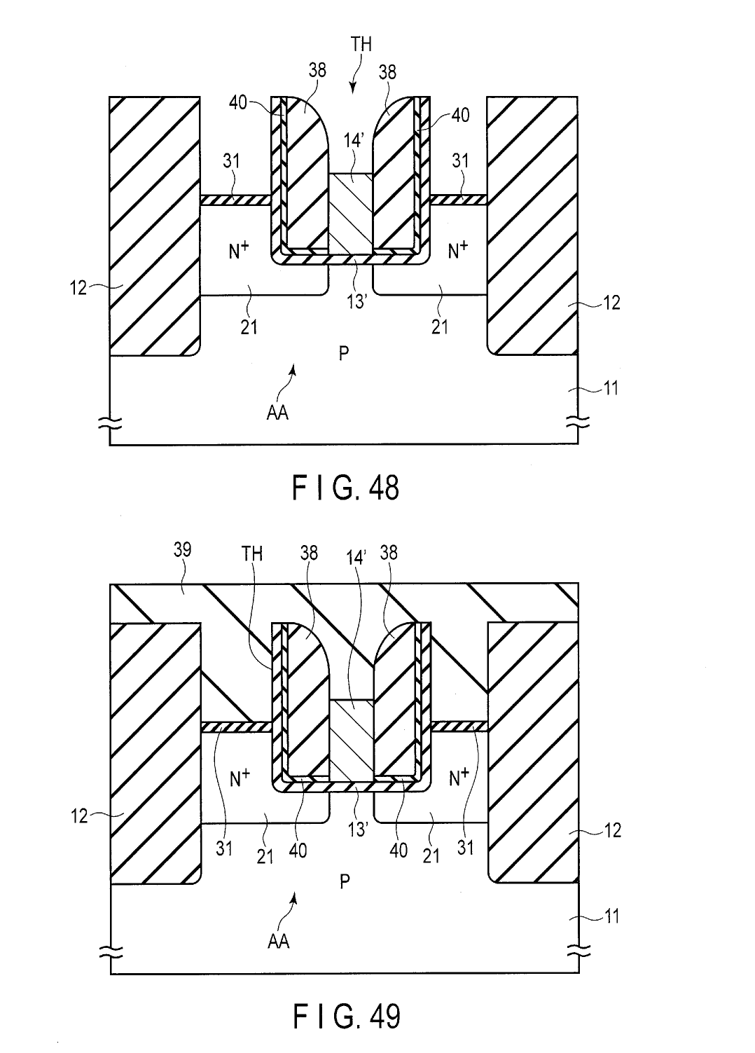

Next, for example, N-type impurities (P, As, etc.) are implanted by ion implantation using the gate electrode 14′ and the gate sidewall insulating layer 38 as masks, as shown in FIG. 48. As a result, the source/drain region (impurity region) 21 is formed inside the semiconductor substrate 11 adjacent to the side surface and the bottom surface of the trench TH.

The top surface of the source/drain region 21 should preferably be lower than the upper surface of the gate electrode 14′ and higher than the lower surface of the gate electrode 14′.

Finally, an interlayer insulating layer 39 to be embedded in the trench TH is formed by the CVD, as shown in FIG. 49. The interlayer insulating layer 39 is, for example, a silicon oxide layer. An upper surface of the interlayer insulating layer 39 is flattened by the CMP.

The device structure (second example) is completed in the above-described manufacturing method.

### CONCLUSION

According to the present embodiment, improvement in a manufacturing yield can be attempted by designing each of the select transistor in the memory cell array and the FET in the peripheral circuit to be in the embedded gate type. In addition, high-speed operations can be implemented by improving the structure of the FET in the peripheral circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A field effect transistor comprising:
a semiconductor layer having a first trench;
a first gate insulating layer on a bottom surface of the first trench;
a first gate electrode on the first gate insulating layer;
first and second impurity regions in the semiconductor layer, the first and second impurity regions exposing on first and second side surfaces of the first trench in a first direction, respectively;
a first gate sidewall insulating layer between the first gate electrode and the first impurity region in the first trench, a width of the first gate sidewall insulating layer in an in-plane direction which is parallel to an upper surface of the semiconductor layer being larger than a thickness of the first gate insulating layer in a perpendicular direction which is perpendicular to the upper surface of the semiconductor layer;
a second gate sidewall insulating layer between the first gate electrode and the second impurity region in the first trench, a width of the second gate sidewall insulating layer in the in-plane direction being larger than the thickness of the first gate insulating layer in the perpendicular direction; and
third and fourth impurity regions in the semiconductor layer, the third and fourth impurity regions exposing on the bottom surface of the first trench, the third impurity region having a impurity concentration lower than that of the first impurity region and being connected to the first impurity region, the fourth impurity region having a impurity concentration lower than that of the second impurity region and being connected to the second impurity region.

2. The transistor of claim 1, wherein
the semiconductor layer has a fin-structure extending in the first direction in the bottom surface of the first trench, and the first gate insulating layer and the first gate electrode cover side surfaces of the semiconductor layer in a second direction which intersects with the first direction.

3. The transistor of claim 1, wherein
each of the first and second gate sidewall insulating layers includes a low-k material which has a dielectric constant lower than that of silicon oxide.

4. The transistor of claim 1, wherein
the first gate insulating layer includes a high-k material which has a dielectric constant higher than that of silicon oxide.

5. The transistor of claim 1, wherein
the third and fourth impurity regions are provided below the first and second gate sidewall insulating layers, respectively.

6. The transistor of claim 1, further comprising:
a compound semiconductor layer below the first gate insulating layer and between the third and fourth impurity regions.

7. The transistor of claim 1, wherein
the third and fourth impurity regions are provided in the semiconductor layer which exposes on the first and second side surfaces of the first trench, respectively.

8. The transistor of claim 1, wherein
an edge between the bottom surface and the first side surface is rounded, and an edge between the bottom surface and the second side surface is rounded.

9. The transistor of claim 1, wherein
the first gate electrode has an upper surface lower than that of the first and second impurity regions.

10. A magnetic memory comprising:
a memory cell array including a memory cell having a select transistor and a magnetoresistive element; and
a peripheral circuit including the field effect transistor of claim 1,
wherein the select transistor comprises:
a second gate insulating layer on a bottom surface of a second trench of the semiconductor layer;
a second gate electrode on the second gate insulating layer, the second gate electrode filling the second trench;
fifth and sixth impurity regions in the semiconductor layer, the fifth and sixth impurity regions exposing on third and fourth side surfaces of the second trench, respectively; and
the second gate electrode has an upper surface lower than that of the fifth and sixth impurity regions.

11. The memory of claim 10, further comprising:
first and second bottom electrodes on the fifth and sixth impurity regions, respectively, the magnetoresistive element being provided on the first bottom electrode;
a first conductive line connected to the magnetoresistive element; and
a second conductive line connected to the second bottom electrode.

12. The memory of claim 10, wherein
the first gate electrode includes a same material as a material of the second gate electrode.

13. A field effect transistor comprising:
a semiconductor layer having a first trench, the semiconductor layer surrounded by an element isolation insulating layer;
a first gate insulating layer on a bottom surface of the first trench;
a first gate electrode on the first gate insulating layer;
first and second impurity regions in the semiconductor layer, the first and second impurity regions exposing on first and second side surfaces of the first trench in a first direction, respectively;
a first gate sidewall insulating layer between the first gate electrode and the first impurity region in the first trench; and
a second gate sidewall insulating layer between the first gate electrode and the second impurity region in the first trench,
wherein the first gate electrode has an upper surface lower than an upper surface of the element isolation insulating layer.

14. The transistor of claim 13, wherein
the semiconductor layer has a fin-structure extending in the first direction in the bottom surface of the first trench, and the first gate insulating layer and the first gate electrode cover side surfaces of the semiconductor layer in a second direction which intersects with the first direction.

15. The transistor of claim 13, wherein
each of the first and second gate sidewall insulating layers includes a low-k material which has a dielectric constant lower than that of silicon oxide.

16. The transistor of claim 13, wherein
the first gate insulating layer includes a high-k material which has a dielectric constant higher than that of silicon oxide.

17. The transistor of claim 13, wherein
the first and second impurity regions are provided below the first and second gate sidewall insulating layers, respectively.

18. The transistor of claim 13, further comprising:
a compound semiconductor layer below the first gate insulating layer and between the third and fourth impurity regions.

19. The transistor of claim 13, wherein
each of the first and second impurity regions has an upper surface lower than the upper surface of the first gate electrode and higher than a lower surface of the first gate electrode.

20. The transistor of claim 13, wherein
an edge between the bottom surface and the first side surface is rounded, and an edge between the bottom surface and the second side surface is rounded.

21. A magnetic memory comprising:
a memory cell array including a memory cell having a select transistor and a magnetoresistive element; and
a peripheral circuit including the field effect transistor of claim 13,
wherein the select transistor comprises:
a second gate insulating layer on a bottom surface of a second trench of the semiconductor layer;
a second gate electrode on the second gate insulating layer, the second gate electrode filling the second trench;
third and fourth impurity regions in the semiconductor layer, the third and fourth impurity regions exposing on third and fourth side surfaces of the second trench, respectively; and
the second gate electrode has an upper surface lower than that of the third and fourth impurity regions.

22. The memory of claim 21, further comprising:
first and second bottom electrodes on the third and fourth impurity regions, respectively, the magnetoresistive element being provided on the first bottom electrode;
a first conductive line connected to the magnetoresistive element; and
a second conductive line connected to the second bottom electrode.

23. The memory of claim 21, wherein
the first gate electrode includes a same material as a material of the second gate electrode.
